(19) United States
(12) Patent Application Publication
(10) Pub. No.: US 2025/0268040 A1
(43) Pub. Date: Aug. 21, 2025

(54) DISPLAY DEVICE, DISPLAY PANEL AND VEHICLE

(71) Applicant: LG Display Co., Ltd., Seoul (KR)

(72) Inventors: Jieun KANG, Paju-si (KR); MinSeo KIM, Paju-si (KR)

(73) Assignee: LG Display Co., Ltd., Seoul (KR)

(21) Appl. No.: 19/039,615

(22) Filed: Jan. 28, 2025

(30) Foreign Application Priority Data
Feb. 21, 2024 (KR) 10-2024-0025252

(51) Int. Cl. H10K 59/131; H10D 86/40; H10D 86/60; H10K 59/121

(52) U.S. Cl. CPC H10K 59/131; H10K 59/1213; H10D 86/441; H10D 86/60

(57) ABSTRACT

A display device, a display panel and a vehicle are discussed. The display device can include a substrate including an active area having a plurality of subpixels and a non-active area outside the active area, a plurality of data lines connected to the plurality of subpixels, a plurality of data link lines electrically connected to the plurality of data lines in the active area, a plurality of power lines disposed in the active area and disposed in the same metal layer as at least one of the plurality of data lines, and a power pattern disposed in the non-display area and electrically connected to at least one of the plurality of power lines.

### CROSS-REFERENCE TO RELATED APPLICATION

This application claims priority to Korean Patent Application No. 10-2024-0025252, filed in the Republic of Korea on Feb. 21, 2024, the entire contents of which are hereby expressly incorporated by reference into the present application.

### BACKGROUND

### Technical Field

Example embodiments of the disclosure relate to a display device, and more particularly, for example, without limitation, to a display device having a data link structure capable of reducing the bezel of the display device.

### Description of Related Art

A display device can include an active area where an image is displayed and a non-active area where an image is not displayed. Various structures, circuits, and lines can be disposed in the non-active area of the display device. Accordingly, it may not be easy to reduce the bezel (e.g., bezel area) of the display panel. In particular, it may not be easy to reduce the bezel because link lines for transferring data signals to data lines are disposed in the non-active area of the display panel.

The description provided in the discussion of the related art section should not be assumed to be prior art merely because it is mentioned in or associated with that section. The discussion of the related art section can include information that describes one or more aspects of the subject technology, and the description in this section does not limit the invention.

### BRIEF SUMMARY OF THE DISCLOSURE

Example embodiments of the disclosure can provide a display device having a data link structure capable of reducing the bezel of the display device.

Example embodiments of the disclosure can provide a display device having a power line structure that enables stable transfer of power voltage.

A display device according to example embodiments of the disclosure can comprise a substrate including an active area including a plurality of subpixels and a non-active area outside the active area, a plurality of data lines connected to the plurality of subpixels, a plurality of data link lines electrically connected to the plurality of data lines in the active area, a plurality of power lines disposed in the active area and disposed in the same metal layer as at least one of the plurality of data lines, and a power pattern disposed in the non-display area and electrically connected to at least one of the plurality of power lines.

A display device according to example embodiments of the disclosure can comprise a substrate including an active area displaying an image and a non-active area outside the active area, a plurality of data link lines electrically connected to a plurality of data lines and disposed in the active area, a plurality of pixel electrodes disposed in the active area, a common electrode overlapping the plurality of pixel electrodes, and a plurality of power lines disposed in the active area in a mesh form and disposed in the same metal layer as the plurality of data link lines and electrically connected to the common electrode or receiving a power voltage applied to the common electrode.

A display device according to example embodiments of the disclosure can comprise a substrate including an active area including a plurality of subpixels and a non-active area outside the active area; a plurality of data lines connected to the plurality of subpixels; a plurality of data link lines electrically connect a plurality of pads in the non-active area and the plurality of data lines in the active area, wherein the plurality of data link lines include a plurality of first data link lines each extending in a first direction in the active area and a plurality of second data link lines each extending in a second direction different from the first direction in the active area, and wherein the plurality of second data link lines electrically connect the plurality of pads and the plurality of first data link lines, the plurality of first data link lines electrically connect the plurality of second data link lines and the plurality of data lines.

A vehicle according to various embodiments of the disclosure can comprise the at least one display device.

A display panel according to various embodiments of the disclosure can comprise a plurality of data lines disposed in the active area; a plurality of pads disposed in the non-active area; and a plurality of data link lines disposed in the active area and non-active area, and configured to electrically connect the plurality of pads and the plurality of data lines, wherein the plurality of data link lines include a plurality of first data link lines each extending in a first direction in the active area and a plurality of second data link lines each extending in a second direction different from the first direction in the active area, and wherein the plurality of second data link lines electrically connect the plurality of pads and the plurality of first data link lines, the plurality of first data link lines electrically connect the plurality of second data link lines and the plurality of data lines.

According to example embodiments of the disclosure, there can be provided a display device having a data link structure capable of reducing the bezel of the display device.

According to example embodiments of the disclosure, there can be provided a display device having a power line structure that enables stable transfer of power voltage.

According to example embodiments of the disclosure, there can be provided a display device having a power line structure suitable for a data link structure capable of reducing the bezel of the display device.

According to example embodiments of the disclosure, there can be provided a display device having a power line structure capable of distributively supplying a power voltage.

According to example embodiments of the disclosure, there can be provided a display device capable of alleviating or preventing heat concentration due to a power voltage.

According to example embodiments of the disclosure, there can be provided a display device having a power line structure capable of reducing an undesired voltage drop of a power voltage.

According to example embodiments of the disclosure, it is possible to reduce the weight of a display device by reducing the bezel by a data link structure capable of reducing the bezel of the display device.

According to example embodiments of the disclosure, it is possible to eliminate the need for increasing the power voltage to be input to the display panel considering a voltage drop by reducing the voltage drop of the power voltage, thereby making it possible to secure an additional voltage usage margin and achieve a low-power design.

Purposes according to the present disclosure are not limited to the above-mentioned purpose. Other purposes and advantages according to the present disclosure that are not mentioned can be understood based on following descriptions, and can be more clearly understood based on embodiments according to the present disclosure. Further, it will be easily understood that the purposes and advantages according to the present disclosure can be realized using means shown in the claims or combinations thereof.

It is to be understood that both the foregoing general description and the following detailed description of the present disclosure are examples and explanatory and are intended to provide further explanation of the disclosure as claimed.

### BRIEF DESCRIPTION OF THE DRAWINGS

The above and other objects, features, and advantages of the disclosure will be more clearly understood from the following detailed description, taken in conjunction with the accompanying drawings, in which:

FIG. 1 is a view illustrating a system configuration of a display device according to example embodiments of the disclosure;

FIG. 2 is a view illustrating a display panel according to an example embodiment of the disclosure;

FIG. 3 is a cross-sectional view illustrating a display panel according to example embodiments of the disclosure;

FIG. 4 illustrates a substrate of a display panel according to example embodiments of the disclosure;

FIG. 5 is a plan view illustrating a display panel according to example embodiments of the disclosure;

FIG. 6 is a plan view illustrating a display panel according to example embodiments of the disclosure;

FIG. 7 illustrates three areas included in an active area of a display panel according to example embodiments of the disclosure;

FIG. 8 is a plan view illustrating a display panel according to example embodiments of the disclosure;

FIGS. 9 and 10 are cross-sectional views illustrating a display panel according to example embodiments of the disclosure;

FIG. 11 is a plan view illustrating an active area of a display panel having a power line structure associated with a data link structure according to example embodiments of the disclosure;

FIG. 12 illustrates a power line structure of a display panel according to example embodiments of the disclosure;

FIG. 13 illustrates a first area of a display panel according to example embodiments of the disclosure;

FIG. 14 illustrates a second area of a display panel according to example embodiments of the disclosure;

FIG. 15 illustrates a third area of a display panel according to example embodiments of the disclosure;

FIG. 16 illustrates a boundary area between a second area and a third area of a display panel according to example embodiments of the disclosure;

FIG. 17 is a plan view illustrating a non-corner area in a display panel according to example embodiments of the disclosure;

FIG. 18 is a plan view illustrating a corner area in a display panel according to example embodiments of the disclosure;

FIG. 19 is a cross-sectional view taken along line X1-X1′ of FIG. 17; and

FIG. 20 is a cross-sectional view taken along line X2-X2′ of FIG. 17.

Throughout the drawings and the detailed description, unless otherwise described, the same drawing reference numerals should be understood to refer to the same elements, features, and structures. The relative size and depiction of these elements can be exaggerated for clarity, illustration, and convenience.

### DETAILED DESCRIPTION OF THE EMBODIMENTS

Reference will now be made in detail to embodiments of the present disclosure, examples of which can be illustrated in the accompanying drawings. The progression of processing steps and/or operations described is an example; however, the sequence of steps and/or operations is not limited to that set forth herein and can be changed as is known in the art, with the exception of steps and/or operations necessarily occurring in a particular order. Names of the respective elements used in the following explanations can be selected only for convenience of writing the specification and can be thus different from those used in actual products.

Hereinafter, embodiments of the disclosure are described in detail with reference to the accompanying drawings. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations. For example, a first element could be termed a second element, and, similarly, a second element could be termed a first element, without departing from the scope of the present disclosure.

In describing the positional relationship between components, when two or more components are described as “connected”, “coupled” or “linked”, the two or more components can be directly “connected”, “coupled” or “linked”, or another component can intervene. Here, the other component can be included in one or more of the two or more components that are “connected”, “coupled” or “linked” to each other.

It should be understood that the term “at least one” includes all combinations related with any one item. For example, “at least one among a first element, a second element and a third element” can include all combinations of two or more elements selected from the first, second and third elements as well as each individual element of the first, second and third elements.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise).

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” can apply, for example, to a separate circuit or structure, an integrated circuit, a computational block of a circuit device, or any structure configured to perform a described function as should be understood to one of ordinary skill in the art. Further, the term “can” fully encompasses all the meanings and coverages of the term “may.”

Hereinafter, various embodiments of the disclosure are described in detail with reference to the accompanying drawings. All the components of each device and each apparatus according to all embodiments of the disclosure are operatively coupled and configured.

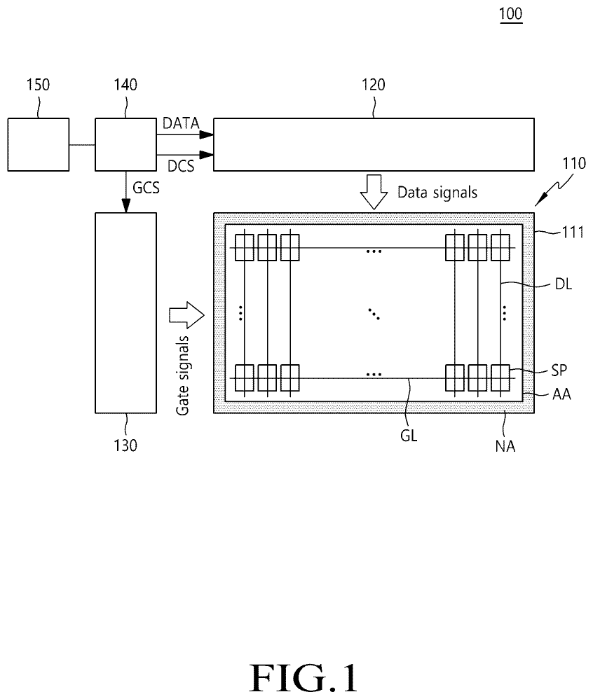

FIG. 1 is a view illustrating a system configuration of a display device 100 according to example embodiments of the disclosure.

Referring to FIG. 1, the display device 100 according to example embodiments of the disclosure can include a display panel 110 and display driving circuits, as components for displaying images. The display driving circuit can be a circuit for driving the display panel 110. The display driving circuits can include a data driving circuit 120, a gate driving circuit 130, and a controller 140, but example embodiments of the disclosure are not limited thereto.

The display panel 110 can include a substrate 111 and a plurality of subpixels SP disposed on the substrate 111.

The substrate 111 can include an active area (display area) AA capable of displaying an image and a non-active area (non-display area) NA positioned around or outside the active area AA. The non-active area NA can surround the display area AA entirely or only in part(s).

The active area AA can also be referred to as a display area, and a plurality of subpixels SP for displaying an image can be disposed in the active area AA. The non-active area NA can also be referred to as a non-display area and can include a pad area PA positioned at at least one side of the display area AA in a column direction.

In the display panel 110 according to example embodiments of the disclosure, the non-active area NA can be very small. In the disclosure, the non-active area NA is also referred to as a “bezel” or an “edge” area. For example, the non-active area NA can include a first non-active area positioned outside the active area AA in the column direction, a second non-active area positioned outside the active area AA in the row direction, a third non-active area positioned outside the active area AA in the column direction and opposite to the first non-active area, and a fourth non-active area positioned outside the active area AA in the row direction and opposite to the second non-active area. The first non-active area among the first to fourth non-active areas can include a pad area where the data driving circuit is connected or bonded. Among the first to fourth non-active areas, the second to fourth non-active areas including no pad area can have a very small size, but example embodiments of the disclosure are not limited thereto.

As another example, the boundary area between the active area AA and the non-active area NA can be bent so that the non-active area NA can be positioned under the active area AA. In this case, as the user views the display device 100 from the front, no or little non-active area NA is visible to the user, but example embodiments of the disclosure are not limited thereto.

Various types of signal lines for driving a plurality of subpixels SP can be disposed on the substrate 111 of the display panel 110. Also, the display panel 110 can include one or more optical areas.

The display device 100 according to example embodiments of the disclosure can be a liquid crystal display device (LCD), a plasma display device (PDP), a field emission display device (FED), or the like, or a self-emission display device in which the display panel 110 emits light by itself, such as an organic light-emitting display device (OLED), and a micro LED (Micro Light Emitting Diode) display device, but example embodiments of the disclosure are not limited thereto. When the display device 100 according to the embodiments of the disclosure is a self-emission display device, each of the plurality of subpixels SP can include a light emitting element.

For example, the display device 100 according to example embodiments of the disclosure can be an organic light emitting diode display in which the light emitting element is implemented as an organic light emitting diode (OLED). As another example, the display device 100 according to example embodiments of the disclosure can be an inorganic light emitting display device in which the light emitting element is implemented as an inorganic material-based light emitting diode. As another example, the display device 100 according to example embodiments of the disclosure can be a quantum dot display device in which the light emitting element is implemented as a quantum dot which is self-emission semiconductor crystal. As another example, the display device 100 according to example embodiments of the disclosure can be a micro LED display device or a mini LED display device.

Each of the plurality of subpixels SP is a minimum unit which configures the display area and n subpixels SP form one pixel. Each of the plurality of subpixels SP can emit light having different wavelengths from each other. The plurality of subpixels can include first to third subpixels which emit different color light from each other. Each pixel P can be divided into a red subpixel, a green subpixel, and a blue subpixel, for color rendering. Each pixel P can further include a white subpixel. The plurality of subpixels SP can be variously modified in colors and configurations, as necessary. However, the present disclosure is not limited thereto.

For example, the plurality of subpixels SP can include red, green, and blue subpixels, in which the red, green, and blue subpixels can be disposed in a repeated manner. Alternatively, the plurality of subpixels SP can include red, green, blue, and white subpixels, in which the red, green, blue, and white subpixels can be disposed in a repeated manner, or the red, green, blue, and white subpixels can be disposed in a quad type. For example, the red sub pixel, the blue sub pixel, and the green sub pixel can be sequentially disposed along a row direction, or the red sub pixel, the blue sub pixel, the green sub pixel and the white sub pixel can be sequentially disposed along the row direction. However, in the embodiment of the present disclosure, the color type, disposition type, and disposition order of the subpixels are not limiting, and can be configured in various forms according to light-emitting characteristics, device lifespans, and device specifications.

Meanwhile, the subpixels can have different light-emitting areas according to light-emitting characteristics. For example, a subpixel that emits light of a color different from that of a blue subpixel can have a different light-emitting area from that of the blue subpixel. For example, the red subpixel, the blue subpixel, and the green subpixel, or the red subpixel, the blue subpixel, the white subpixel, and the green subpixel can each has a different light-emitting area.

The structure of each of the plurality of subpixels SP can vary according to the type of the display device 100. For example, when the display device 100 is a self-emission display device in which the subpixels SP emit light by themselves, each subpixel SP can include a light emitting element that emits light by itself, one or more transistors, and one or more capacitors, but embodiments of the disclosure are not limited thereto.

For example, various types of signal lines can include a plurality of data lines DL for transferring data signals (also referred to as data voltages or image signals) and a plurality of gate lines GL for transferring gate signals (also referred to as scan signals), and the like.

The plurality of data lines DL and the plurality of gate lines GL can cross each other. Each of the plurality of data lines DL can be disposed to extend in the column direction. Each of the plurality of gate lines GL can be disposed to extend in the row direction. According to example embodiments of the disclosure, the column direction and the row direction can be relative directions. For example, the column direction can be the row direction depending on the viewpoint, and the row direction can be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto. In embodiments of the disclosure, the angle between the row direction and the column direction can be 90 degrees or can an angle different from 90 degrees. Further, in embodiments of the disclosure, the row direction can be referred to as a first direction, and the column direction can be referred to as a second direction. Alternatively, the column direction can be referred to as a first direction, and the row direction can be referred to as a second direction.

The data driving circuit 120 can be a circuit for driving a plurality of data lines DL. The data driving circuit 120 can output data signals to the plurality of data lines DL. The gate driving circuit 130 can be a circuit for driving a plurality of gate lines GL, and can supply gate signals to the plurality of gate lines GL.

The data driving circuit 120 can receive digital image data DATA from the controller 140 and can convert the received image data DATA into analog data signals and output them to the plurality of data lines DL.

For example, the data driving circuit 120 can be connected with the display panel 110 by a tape automated bonding (TAB) method or connected to a conductive pad such as a bonding pad of the display panel 110 by a chip on glass (COG) or chip on panel (COP) method or can be implemented by a chip on film (COF) method and connected with the display panel 110, but embodiments of the disclosure are not limited thereto.

The data driving circuit 120 can be connected to one side (e.g., an upper or lower side) of the display panel 110. In contrast, depending on the driving scheme or the panel design scheme, or the like, data driving circuits 120 can be connected with both the sides (e.g., both the upper and lower sides) of the display panel 110, or two or more of the four sides (e.g., the upper edge, the lower edge, a left edge, and a right edge) of the display panel 110.

The data driving circuit 120 can be connected outside the active area AA of the display panel 110, but as another example, the data driving circuit 120 can be disposed in the active area AA of the display panel 110.

The gate driving circuit 130 is a circuit for driving the plurality of gate lines GL, and can output gate signals to the plurality of gate lines GL.

The gate driving circuit 130 can receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to example embodiments of the disclosure, the gate driving circuit 130 can be embedded, in a gate in panel (GIP) type, in the display panel 110. When the gate driving circuit 130 is of the gate in panel type, the gate driving circuit 130 can be formed on the substrate 111 of the display panel 110 during the manufacturing process of the display panel 110.

For example, the gate driving circuit 130 can be disposed in the non-active area NA of the display panel 110.

As another example, the gate driving circuit 130 can be disposed in the active area AA of the display panel 110. In this case, for example, the gate driving circuit 130 can be disposed in a first partial area in the active area AA (e.g., a left area or a right area in the active area AA). As another example, the gate driving circuit 130 can be disposed in a first partial area in the active area AA (e.g., a left area or right area in the active area AA) and a second partial area (e.g., a right area or left area in the active area AA).

In the disclosure, the gate driving circuit 130 embedded in the display panel 110 in a gate-in-panel type can also be referred to as a “gate-in-panel circuit.” The gate driving circuit 130 can be disposed on the substrate 111, or connected to the substrate 111.

The controller 140 is a device for controlling the data driving circuit 120 and the gate driving circuit 130 and can control driving timings for the plurality of data lines DL and driving timings for the plurality of gate lines GL.

The controller 140 can supply a data driving control signal DCS to the data driving circuit 120 to control the data driving circuit 120 and can supply a gate driving control signal GCS to the gate driving circuit 130 to control the gate driving circuit 130.

The controller 140 can receive input image data from the host system 150 and supply image data DATA to the data driving circuit 120 based on the input image data.

The controller 140 can be implemented as a separate component from the data driving circuit 120, or the controller 140 and the data driving circuit 120 can be integrated into an integrated circuit (IC). However, the present disclosure is not limited thereto.

The controller 140 can be a timing controller used in display technology, a controller or a control device that can perform other control functions as well as the functions of the timing controller, or a control device other than the timing controller, or can be a circuit or a component included in the controller or the control device. The controller 140 can be implemented as various circuits or electronic components, such as an integrated circuit (IC), a field programmable gate array (FPGA), an application specific integrated circuit (ASIC), or a processor, but is not limited thereto.

The controller 140 can be mounted on a printed circuit board or a flexible printed circuit and can be electrically connected with the data driving circuit 120 and the gate driving circuit 130 through the printed circuit board or the flexible printed circuit, and/or the like.

The controller 140 can transmit/receive signals to/from the data driving circuit 120 according to one or more predetermined interfaces. The interface can include, e.g., a low voltage differential signaling (LVDS) interface, an embedded clock point-point interface (EPI) interface, and a serial peripheral interface (SPI), but embodiments of the disclosure are not limited thereto. Similarly, the controller 240 can transmit signals to, and receive signals from, the gate driving circuit 130 via one or more predefined interfaces.

To provide a touch sensing function as well as an image display function, the display device 100 according to example embodiments of the disclosure can include a touch sensor and a touch sensing circuit that senses the touch sensor to detect whether a touch occurs by a touch object, such as a finger or pen, or the position of the touch. The touch sensor can be a touch unit.

The touch sensing circuit can include, but is not limited to, a touch driving circuit that drives and senses the touch sensor and generates and outputs touch sensing data and a touch controller that can detect an occurrence of a touch or the position of the touch using touch sensing data.

The touch sensor can include a plurality of touch electrodes. The touch sensor can further include a plurality of touch lines for electrically connecting the plurality of touch electrodes and the touch driving circuit.

The touch sensor can be present in a touch panel form outside of the display panel 110 or can be present inside of the display panel 110. When the touch panel, in the form of a touch panel, exists outside the display panel 110, the touch panel is of an external type. When the touch sensor is of the external type, the touch panel and the display panel 110 can be separately manufactured or can be combined during an assembly process. The external-type touch panel can include a touch panel substrate and a plurality of touch electrodes on the touch panel substrate.

When the touch sensor is present inside of the display panel 110, the touch sensor can be formed on the substrate, together with signal lines and electrodes related to display driving, during the manufacturing process of the display panel 110.

The touch driving circuit can supply a touch driving signal to at least one of the plurality of touch electrodes and can sense at least one of the plurality of touch electrodes to generate touch sensing data.

The touch sensing circuit can perform touch sensing in a self-capacitance sensing scheme or a mutual-capacitance sensing scheme, without being limited thereto.

When the touch sensing circuit performs touch sensing in the self-capacitance sensing scheme, the touch sensing circuit can perform touch sensing based on capacitance between each touch electrode and the touch object (e.g., finger or pen). According to the self-capacitance sensing scheme, each of the plurality of touch electrodes can serve both as a driving touch electrode and as a sensing touch electrode. The touch driving circuit can drive all or some of the plurality of touch electrodes and sense all or some of the plurality of touch electrodes.

When the touch sensing circuit performs touch sensing in the mutual-capacitance sensing scheme, the touch sensing circuit can perform touch sensing based on capacitance between the touch electrodes. According to the mutual-capacitance sensing scheme, the plurality of touch electrodes are divided into driving touch electrodes and sensing touch electrodes. The touch driving circuit can drive the driving touch electrodes and sense the sensing touch electrodes.

The touch driving circuit and the touch controller included in the touch sensing circuit can be implemented as separate devices or as a single device, without being limited thereto. The touch driving circuit and the data driving circuit can be implemented as separate devices or as a single device, without being limited thereto.

The display device 100 can further include a power supply circuit for supplying various types of power to the display driver integrated circuit and/or the touch sensing circuit. The power supply circuit can supply various voltages and power voltages related to display driving to the display driving circuit or display panel 110.

The display device 100 according to example embodiments of the disclosure can be a mobile terminal, such as a notebook computer, a smart phone or a tablet, or a monitor or television (TV) in various sizes but, without limited thereto, can be a display in various types and various sizes capable of displaying information or images.

The display device 100 according to example embodiments of the disclosure can further include an electronic device such as a camera (image sensor), a detection sensor, or the like. For example, the detection sensor can be a sensor that detects an object or a human body by receiving light such as infrared rays, ultrasonic waves, or ultraviolet rays.

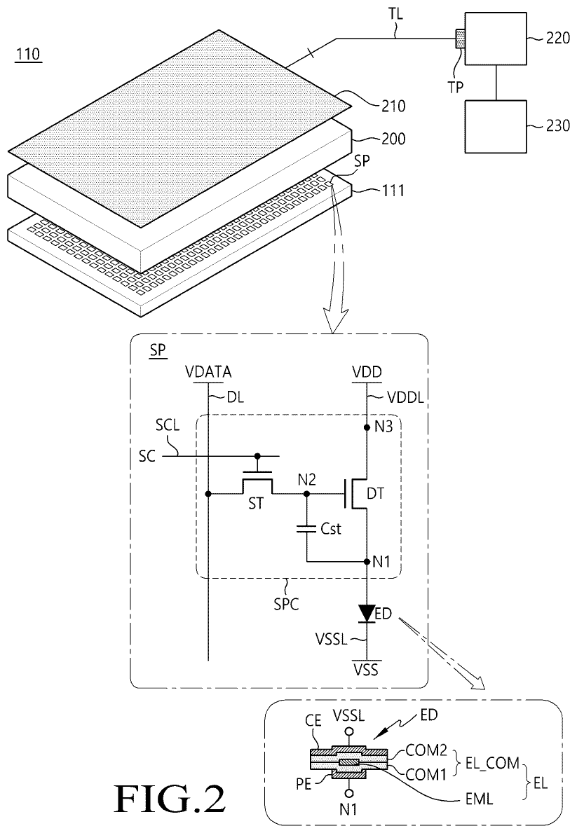

FIG. 2 illustrates a display panel 110 according to an example embodiment of the disclosure.

Referring to FIG. 2, the display panel 110 can include a substrate 111 disposed with plurality of subpixels SP and an encapsulation layer 200 on the substrate 111. The encapsulation layer 200 can also be referred to as an encapsulation substrate or an encapsulation portion.

When the display device 100 according to example embodiments of the disclosure is a self-luminous display device, each of the plurality of subpixels SP disposed on the substrate 111 can include a light emitting element ED and a subpixel circuit SPC for driving the light emitting element ED.

The subpixel circuit SPC can include a plurality of transistors and at least one capacitor for driving the light emitting element ED, but embodiments of the disclosure are not limited thereto. In the disclosure, the subpixel circuit SPC can drive the light emitting element ED by supplying a driving current to the light emitting element ED at a predetermined timing. The light emitting element ED can be driven by a driving current to emit light.

The plurality of transistors can include a driving transistor DT for driving the light emitting element ED and a scan transistor ST that is turned on or off according to the scan signal SC.

The driving transistor DT can supply a driving current to the light emitting element ED.

The scan transistor ST can be configured to control the electrical state of a corresponding node in the subpixel circuit SPC or to control the state or operation of the driving transistor DT.

The at least one capacitor can include a storage capacitor Cst for maintaining a constant voltage during a frame. The storage capacitor Cst can be disposed between a first node N1 and a second node N2 of the driving transistor DT.

To drive the subpixel SP, a data signal VDATA as an image signal and a scan signal SC as a gate signal can be applied to the subpixel SP. Further, for driving the subpixel SP, a common pixel driving voltage including the first common driving voltage VDD and the second common driving voltage VSS can be applied to the subpixel SP.

The light emitting element ED can include a pixel electrode PE, an intermediate layer EL, and a common electrode CE. The intermediate layer EL can be disposed between the pixel electrode PE and the common electrode CE.

For example, the pixel electrode PE can be an electrode disposed in each subpixel SP, and the common electrode CE can be an electrode commonly disposed in all the subpixels SP. For example, the pixel electrode PE can be an anode, and the common electrode CE can be a cathode, but embodiments of the disclosure are not limited thereto. As another example, the pixel electrode PE can be a cathode, and the common electrode CE can be an anode. For convenience of description, an example is described in which the pixel electrode PE is an anode, and the common electrode CE is a cathode.

When the light emitting element ED is an organic light emitting element, the intermediate layer EL can include a light emitting layer EML, a first common intermediate layer COM1 between the pixel electrode PE and the light emitting layer EML, and a second common intermediate layer COM2 between the light emitting layer EML and the common electrode CE. The first common intermediate layer COM1 and the second common intermediate layer COM2 can be collectively referred to as a common intermediate layer EL_COM.

The light emitting layer EML can be disposed for each subpixel SP. The common intermediate layer EL_COM can be commonly disposed over the plurality of subpixels SP.

The light emitting layer EML can be disposed for each emission area. The common intermediate layer EL_COM can be commonly disposed across a plurality of emission areas and non-emission areas.

For example, the first common intermediate layer COM1 can include a hole injection layer HIL and a hole transport layer HTL, but embodiments of the disclosure are not limited thereto. The second common intermediate layer COM2 can include an electron transport layer ETL and an electron injection layer EIL.

The hole injection layer can inject holes from the pixel electrode PE to the hole transport layer, the hole transport layer can transport the holes to the light emitting layer EML, the electron injection layer can inject electrons from the common electrode CE to the electron transport layer, and the electron transport layer can transport electrons to the light emitting layer EML.

For example, the common electrode CE can be electrically connected to the second common driving voltage line VSSL. The second common driving voltage VSS, which is one type of common pixel driving voltage, can be applied to the common electrode CE through the second common driving voltage line VSSL. The pixel electrode PE can be electrically connected directly or indirectly (through another transistor) to the first node N1 of the driving transistor DT of each subpixel SP. In the disclosure, “the second common driving voltage VSS” can also be referred to as a “base voltage”, and “the second common driving voltage line VSSL” can also be referred to as a “low-potential power voltage line” or “base voltage line”.

Each light emitting element ED can include portions where the pixel electrode PE, the light emitting layer in the intermediate layer LE, and the common electrode CE overlap. A predetermined light emitting area can be formed by each light emitting element ED. For example, the light emitting area of each light emitting element ED can include an overlapping area of the pixel electrode PE, the intermediate layer EL, and the common electrode CE.

For example, the light emitting element ED can be an organic light emitting diode (OLED), an inorganic light emitting diode (LED), or a quantum dot light emitting element. For example, when the light emitting element ED is an organic light emitting diode (OLED), the intermediate layer EL of the light emitting element ED can include an intermediate layer EL including an organic material.

The driving transistor DT can be a driving transistor for supplying a driving current to the light emitting element ED. The driving transistor DT can be connected between the first common driving voltage line VDDL and the light emitting element ED.

The driving transistor DT can include a first node N1, a second node N2, and a third node N3. The first node N1 can be electrically connected to the light emitting element ED, the second node N2 can receive a data signal VDATA, and the third node N3 can receive a first common driving voltage VDD from the first common driving voltage line VDDL. The driving transistor DT can be connected between the first node N1 and the third node N3.

In the driving transistor DT, the second node N2 can be a gate node, the first node N1 can be a source node or a drain node, and the third node N3 can be a drain node or a source node. Hereinafter, for convenience of description, an example is described in which in the driving transistor DT, the second node N2 can be a gate node, the first node N1 can be a source node, and the third node N3 can be a drain node, but embodiments of the disclosure are not limited thereto.

The scan transistor ST included in the subpixel circuit SPC illustrated in FIG. 2 can be a switching transistor for transferring the data signal VDATA, which is an image signal, to the second node N2, which is the gate node of the driving transistor DT.

The scan transistor ST included in the subpixel circuit SPC can be disposed between the data lines DL and the second node N2, which is the gate node of the driving transistor DT. The scan transistor ST can be turned on or off in response to the scan signal SC applied through the scan line SCL.

For example, the scan transistor ST can be controlled to be turned on and off by the scan signal SC, which is a gate signal applied through the scan line SCL, which is a type of the gate line GL, to control electrical connection between the second node N2 of the driving transistor DT and the data line DL. The drain electrode or the source electrode of the scan transistor ST can be electrically connected to the data line DL, the source electrode or the drain electrode of the scan transistor ST can be electrically connected to the second node N2 of the driving transistor DT, and the gate electrode of the scan transistor ST can be electrically connected to the scan line SCL.

The storage capacitor Cst can be electrically connected between the first node N1 and second node N2 of the driving transistor DT. The storage capacitor Cst can include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The capacitor Cst can be an external capacitor intentionally designed to be outside the driving transistor DT, but not a parasite capacitor (e.g., Cgs or Cgd) which is an internal capacitor that can be present between the first node N1 and the second node N2 of the driving transistor DT.

Each of the driving transistor DT and the scan transistor ST can be an n-type transistor or a p-type transistor.

The display panel 110 can have a top emission structure or a bottom emission structure, or a double-sided emission structure.

When the display panel 110 has a top emission structure, at least a portion of the subpixel circuit SPC can overlap at least a portion of the light emitting element ED in a vertical direction. Accordingly, the area of the light emitting area can increase and the aperture ratio can increase.

When the display panel 110 has a bottom emission structure, the subpixel circuit SPC may not overlap the light emitting element ED in the vertical direction.

As illustrated in FIG. 2, the subpixel circuit SPC can have a 2T (Transistor)1C (Capacitor) structure including two transistors DT and ST and one capacitor Cst. In some cases, the subpixel circuit SPC can further include one or more transistors or can further include one or more capacitors, but embodiments of the disclosure are not limited thereto.

For example, the subpixel circuit SPC can have an 8T1C structure including 8 transistors and 1 capacitor. As another example, the subpixel circuit SPC can have a 6T2C structure including 6 transistors and 2 capacitors. As another example, the subpixel circuit SPC can have a 7T1C structure including 7 transistors and 1 capacitor. Embodiments of the disclosure are not limited thereto. Alternatively, the subpixel circuit SPC can have a 3T1C, 4T1C, 5T1C, 3T2C, 4T2C, 5T2C, 7T2C, 8T2C structures, etc. And more or less transistors and capacitors could be included.

Depending on the structure of the subpixel circuit SPC, the type and number of gate lines or the gate signals supplied to the subpixel SP can vary. Further, the type and the number of common pixel driving voltages supplied to the subpixel SP can vary according to the structure of the subpixel circuit SPC.

Since the circuit elements (e.g., the light emitting element ED implemented as an organic light emitting diode (OLED) including an organic material) in each subpixel SP are vulnerable to external moisture or oxygen, the encapsulation layer 200 for preventing external moisture or oxygen from penetrating into the circuit elements (e.g., the light emitting element ED) can be disposed on the display panel 110. The encapsulation layer 200 can be configured in various forms so that the light emitting elements ED do not contact moisture or oxygen. For example, the encapsulation layer 200 can be constituted of two or more layers in which organic films and inorganic films are alternately stacked, but embodiments of the disclosure are not limited thereto. For example, the encapsulation layer 200 can have a structure in which at least one organic film is disposed between inorganic films.

The inorganic films can include an inorganic insulating material. For example, the inorganic films can include an inorganic insulating material capable of low-temperature deposition, such as silicon nitride (SiN), silicon oxide (SiO), silicon oxynitride (SiON) and aluminum oxide (Al₂O₃), without being limited thereto.

The organic films can include an organic insulating material, such as acrylic resin, epoxy resin, polyimide, polyethylene and silicon oxycarbide (SiOC), without being limited thereto.

Referring to FIG. 2, the display device 100 according to example embodiments of the disclosure can include a touch sensor layer 210 including a plurality of sensor electrodes to sense the user's touch, a touch driving circuit 220 configured to sense the plurality of sensor electrodes, and a touch controller 230 configured to determine the presence or absence of a touch or touch coordinates using the sensing result (touch sensing data) of the touch driving circuit 220.

The touch sensor layer 210 can be embedded in the display panel 110. For example, the touch sensor layer 210 can be disposed on the encapsulation layer 200 in the display panel 110.

The display panel 110 can further include a plurality of touch pads TP electrically connected to the touch driving circuit 220 and a plurality of touch routing lines for electrically connecting the plurality of sensor electrodes included in the touch sensor layer 210 to the plurality of touch pads TP connected to the touch driving circuit 220.

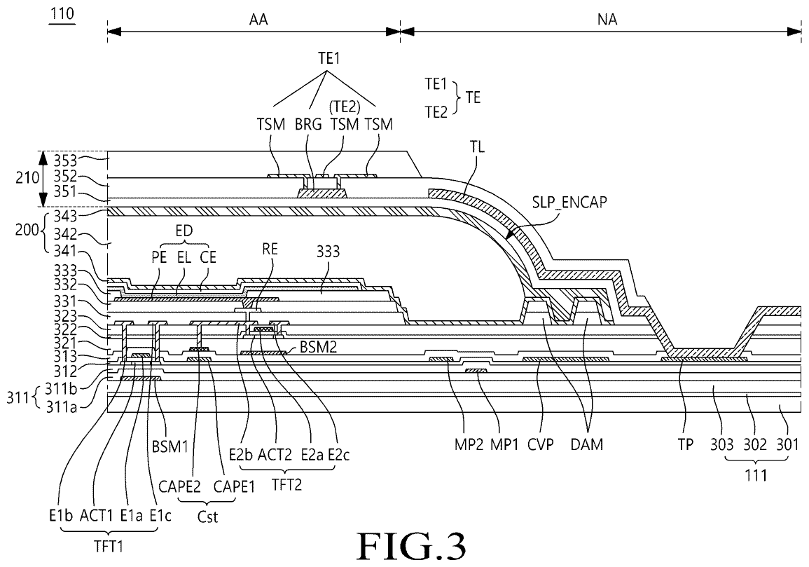

FIG. 3 is a cross-sectional view of a display panel 110 according to example embodiments of the disclosure.

Referring to FIG. 3, the display panel 110 according to example embodiments of the disclosure can include a transistor unit, a light emitting element unit, and an encapsulation unit. For example, the display panel 110 can include a transistor unit, a light emitting element unit, and an encapsulation unit from a vertical structure perspective.

The substrate 111 can be a single layer or multiple layers. When the substrate 111 includes multiple layers, the substrate 111 can include a first substrate 301, an intermediate layer 302, and a second substrate 303, but embodiments of the disclosure are not limited thereto. The intermediate layer 302 can be positioned between the first substrate 301 and the second substrate 303. For example, each of the first substrate 301 and the second substrate 303 can be a polyimide (PI) layer, but embodiments of the disclosure are not limited thereto. Alternatively, the each of the first substrate 301 and the second substrate 303 can be glass, plastic layer, but embodiments of the disclosure are not limited thereto. The intermediate layer 302 can be an inorganic insulation layer. When an electric charge is charged to the first substrate 301 which is a polyimide layer, the intermediate layer 302 can prevent the electric charge from affecting transistors disposed on the second substrate 303 through the second substrate 303 which is a polyimide layer.

Further, the intermediate layer 302 can prevent a moisture component from penetrating upward through the first substrate 301. For example, the intermediate layer 302 can be formed of a single layer of silicon nitride (SiNx) or silicon oxide (SiOx) or multiple layers thereof, or can be formed of a double layer of silicon dioxide (SiO₂) and silicon nitride (SiNx), but is not limited thereto.

The transistor unit can include a substrate 111, various insulation layers 311, 312, 313, 321, 322, and 323 on the substrate 111, various transistors TFT1 and TFT2, a storage capacitor Cst, and various electrodes or signal lines, but embodiments of the disclosure are not limited thereto.

The transistors TFT1 and TFT2 included in the transistor unit can include a first transistor TFT1 and a second transistor TFT2.

The first transistor TFT1 can include a first active layer ACT1, a first electrode Ela, a second electrode Elb, and a third electrode Elc. The first active layer ACT1 can be disposed on the first buffer layer 311. The first active layer ACT1 can be a first semiconductor layer, but embodiments of the disclosure are not limited thereto. For example, the first active layer ACT1 can be formed of an oxide semiconductor, amorphous silicon, polysilicon, or low temperature polysilicon (LTPS), but embodiments of the disclosure are not limited thereto. The first transistor TFT1 can be implemented as a p-channel transistor or an n-channel thin film transistor, but embodiments of the disclosure are not limited thereto.

The first electrode Ela can be a gate electrode, the second electrode E1b can be a source electrode or a drain electrode, and the third electrode E1c can be a drain electrode or a source electrode. Hereinafter, for convenience of description, the first electrode Ela is referred to as a first gate electrode Ela, the second electrode E1b is referred to as a first source electrode E1b, and the third electrode E1c is referred to as a first drain electrode E1c. However, embodiments of the disclosure are not limited thereto.

The second transistor TFT2 can include a second active layer ACT2, a fourth electrode E2a, a fifth electrode E2b, and a sixth electrode E2c. The second active layer ACT2 can be disposed on the second buffer layer 321. The second active layer ACT2 can be a second semiconductor layer, but embodiments of the disclosure are not limited thereto. For example, the second active layer ACT2 can be formed of an oxide semiconductor, amorphous silicon, polysilicon, or low temperature polysilicon (LTPS), but embodiments of the disclosure are not limited thereto. The second transistor TFT2 can be implemented as a p-channel transistor or an n-channel thin film transistor, but embodiments of the disclosure are not limited thereto.

The fourth electrode E2a can be a gate electrode, the fifth electrode E2b can be a source electrode or a drain electrode, and the sixth electrode E2c can be a drain electrode or a source electrode. Hereinafter, for convenience of description, the fourth electrode E2a is referred to as a second gate electrode E2a, the fifth electrode E2b is referred to as a second source electrode E2b, and the sixth electrode E2c is referred to as a second drain electrode E2c. However, embodiments of the disclosure are not limited thereto.

For example, one of the first transistor TFT1 and the second transistor TFT2 can constitute an oxide semiconductor as an active layer. As another example, one of the first transistor TFT1 and the second transistor TFT2 can use low-temperature polysilicon as an active layer. As another example, the first transistor TFT1 and the second transistor TFT2 can configure an oxide semiconductor as an active layer. As another example, the first transistor TFT1 and the second transistor TFT2 can configure low-temperature polysilicon as an active layer. As another example, of the first transistor TFT1 and the second transistor TFT2, the driving transistor DT can configure an oxide semiconductor as an active layer, and the scan transistor ST can configure low-temperature polysilicon as an active layer. As another example, of the first transistor TFT1 and the second transistor TFT2, the driving transistor DT can configure low-temperature polysilicon as an active layer, and the scan transistor ST can configure an oxide semiconductor as an active layer. As another example, a transistor included in a gate driving circuit 130 of a gate in panel (GIP) type can configure an oxide semiconductor or low-temperature polysilicon as an active layer. As another example, all the transistors configured on the substrate 111 and transistors included in a gate driving circuit 130 of a gate in panel (GIP) type can configure an oxide semiconductor as an active layer.

The second active layer ACT2 of the second transistor TFT2 can be positioned higher from the substrate 111 than the first active layer ACT1 of the first transistor TFT1.

The first buffer layer 311 can be disposed under the first active layer ACT1 of the first transistor TFT1, and a second buffer layer 321 can be disposed under the second active layer ACT2 of the second transistor TFT2. For example, the first active layer ACT1 of the first transistor TFT1 can be positioned on the first buffer layer 311, and the second active layer ACT2 of the second transistor TFT2 can be positioned on the second buffer layer 321. The second buffer layer 321 can be positioned higher than the first buffer layer 311. That is, the second active layer ACT2 positioned on the second buffer layer 321 can be positioned higher from the substrate 111 than the first active layer ACT1 disposed on the first buffer layer 311.

The storage capacitor Cst can be disposed in various metal layers in the display panel 110. For example, the storage capacitor Cst can include a first capacitor electrode CAPE1 and a second capacitor CAPE2. For example, the second capacitor CAPE2 can be disposed above the first capacitor electrode CAPE1 with the first inter-layer insulation layer 313 disposed therebetween.

The light emitting element unit can include a plurality of light emitting elements ED disposed on at least one planarization layer 331 and 332. Each of the plurality of light emitting elements ED can include a pixel electrode PE, an intermediate layer EL, and a common electrode CE. The intermediate layer EL can be disposed between the pixel electrode PE and the common electrode CE, and the pixel electrode PE can be disposed on the second planarization layer 332.

The encapsulation unit can include an encapsulation layer 200 on the plurality of light emitting elements ED. The encapsulation layer 200 can be a single layer or multiple layers. The encapsulation portion can further include a dam DAM in addition to the encapsulation layer 200.

Hereinafter, a vertical structure of the display panel 110 according to example embodiments of the disclosure is described in more detail with reference to FIG. 3.

Referring to FIG. 3, the first buffer layer 311 can be disposed on the substrate 111. The first buffer layer 311 can be a single layer or multiple layers. When the first buffer layer 311 includes multiple layers, the first buffer layer 311 can include a lower buffer layer 311a and an upper buffer layer 311b disposed on the lower buffer layer 311a.

The first active layer ACT1 of the first transistor TFT1 can be disposed on the first buffer layer 311. For example, the first active layer ACT1 of the first transistor TFT1 can be disposed on the upper buffer layer 311b. The first active layer ACT1 can include a channel area in which a channel is formed, a source connection area on one side of the channel area, and a drain connection area on the other side of the channel area.

The first gate insulation layer 312 can be disposed on the first active layer ACT1 of the first transistor TFT1. The first gate electrode Ela of the first transistor TFT1 can be disposed on the first gate insulation layer 312. The first inter-layer insulation layer 313 can be disposed on the first gate electrode Ela of the first transistor TFT1. For example, the first inter-layer insulation layer 313 can be disposed on the first gate electrode Ela of the first transistor TFT1 and a portion of the first gate insulation layer 312.

The second buffer layer 321 can be disposed on the first inter-layer insulation layer 313. Also, the second buffer layer 321 can be disposed on the second capacitor CAPE2 of the storage capacitor Cst.

The second active layer ACT2 of the second transistor TFT2 can be disposed on the second buffer layer 321. The second active layer ACT2 can include a channel area in which a channel is formed, a source connection area on one side of the channel area, and a drain connection area on the other side of the channel area.

The second gate insulation layer 322 can be disposed on the second active layer ACT2 of the second transistor TFT2. Specifically, the second gate insulation layer 322 can be disposed on the second active layer ACT2 of the second transistor TFT2 and a portion of the second buffer layer 321. The second gate electrode E2a of the second transistor TFT2 can be disposed. The second inter-layer insulation layer 323 can be disposed on the second gate electrode E2a of the second transistor TFT2.

The first source electrode E1b and the first drain electrode E1c of the first transistor TFT1, and the second source electrode E2b and the second drain electrode E2c of the second transistor TFT2 can be disposed on the second inter-layer insulation layer 323.

The first source electrode E1b and the first drain electrode E1c of the first transistor TFT1 can be connected to the source connection area and the drain connection area, respectively, of the first active layer ACT1 through holes of the second inter-layer insulation layer 323, the second gate insulation layer 322, the second buffer layer 321, the first inter-layer insulation layer 313, and the first gate insulation layer 312.

The second source electrode E2b and the second drain electrode E2c of the second transistor TFT2 can be connected to the source connection area and the drain connection area, respectively, of the second active layer ACT2 through the holes of the second inter-layer insulation layer 323 and the second gate insulation layer 322.

The first source electrode E1b and the first drain electrode E1c of the first transistor TFT1, and the second source electrode E2b and the second drain electrode E2c of the second transistor TFT2 can include a first metal and can be disposed in the first metal layer. The first metal and the first metal layer can be referred to as a first source-drain metal and a first source-drain metal layer.

For example, the storage capacitor Cst can be formed by a first capacitor electrode CAPE1 and a second capacitor electrode CAPE2. In some cases, the storage capacitor Cst can be formed by three or more capacitor electrodes, or can have a form in which two or more capacitors are connected in parallel, but embodiments of the disclosure are not limited thereto.

Each of the first capacitor electrode CAPE1 and the second capacitor electrode CAPE2 can be disposed on various metal layers disposed in the display panel 110.

For example, the first capacitor electrode CAPE1 can include the same first gate metal as the first gate electrode Ela of the first transistor TFT1 on the first gate insulation layer 312, and can be disposed in the first gate metal layer, but embodiments of the disclosure are not limited thereto.

For example, the second capacitor electrode CAPE2 can be disposed on the first inter-layer insulation layer 313. The first inter-layer insulation layer 313 can be disposed between the first capacitor electrode CAPE1 and the second capacitor electrode CAPE2.

The second source electrode E2b of the second transistor TFT2 can be electrically connected to the second capacitor electrode CAPE2 through holes of the second inter-layer insulation layer 323, the second gate insulation layer 322, and the second buffer layer 321.

For example, the first transistor TFT1 can be the scan transistor ST of FIG. 2, and the second transistor TFT2 can be the driving transistor DT of FIG. 2, but embodiments of the disclosure are not limited thereto.

The transistor unit can further include various metal layers MP1 and MP2. For example, the first metal layer MP1 can be disposed between the lower buffer layer 311a and the upper buffer layer 311b included in the first buffer layer 311. The second metal layer MP2 can include the same first gate metal as the first gate electrode Ela of the first transistor TFT1, and can be disposed in the first gate metal layer. The first metal layer MP1 can be a first metal pattern, and the second metal layer MP2 can be a second metal pattern, but embodiments of the disclosure are not limited thereto.

Each of the first metal layer MP1 and the second metal layer MP2 can be disposed in the active area AA or the non-active area NA.

The transistor unit can further include a first shield metal BSM1 disposed on the substrate 111. The first shield metal BSM1 can overlap the first active layer ACT1 of the first transistor TFT1. The first shield metal BSM1 can be disposed under the first active layer ACT1 of the first transistor TFT1. For example, the first shield metal BSM1 can be disposed between the substrate 111 and the first buffer layer 311, or can be disposed between the lower buffer layer 311a and the upper buffer layer 311b.

The transistor unit can further include a second shield metal BSM2 disposed on the substrate 111. The second shield metal BSM2 can overlap the second active layer ACT2 of the second transistor TFT2. The second shield metal BSM2 can be disposed under the second active layer ACT2 of the second transistor TFT2. For example, the second shield metal BSM2 can be disposed between the second buffer layer 321 and the first inter-layer insulation layer 313.

For example, the second shield metal BSM2 can be disposed in a metal layer between the first inter-layer insulation layer 313 and the second buffer layer 321. The second shield metal BSM2 can be disposed in the same metal layer as the second capacitor CAPE2.

As another example, the second shield metal BSM2 can be disposed in the same first gate metal layer as the first gate electrode Ela of the first transistor TFT1.

The transistor unit can further include a common driving voltage layer CVP to which a common driving voltage is applied. For example, the common driving voltage applied to the common driving voltage layer CVP can also be referred to as a power signal, and can be a first common driving voltage VDD or a second common driving voltage VSS. The first common driving voltage VDD can also be referred to as a high-potential power voltage (high-potential power signal), and the second common driving voltage VSS can also be referred to as a low-potential power voltage (low-potential power signal) or a base voltage. The common driving voltage layer CVP can be a common driving voltage pattern or a voltage pattern, but embodiments of the disclosure are not limited thereto.

The common driving voltage layer CVP can be disposed in the active area AA or the non-active area NA.

At least one planarization layer can be disposed on the first transistor TFT1 and the second transistor TFT2. In the example of FIG. 3, two planarization layers 331 and 332 are disposed on the first transistor TFT1 and the second transistor TFT2. In some cases, three or more planarization layers can be disposed on the first transistor TFT1 and the second transistor TFT2, but embodiments of the disclosure are not limited thereto.

The planarization layers 331 and 332 can be formed of one or more materials of acrylic resin, epoxy resin, phenolic resin, polyamides resin, unsaturated polyesters resin, polyphenylene resin, polyphenylene sulfides resin, and benzocyclobutene, but embodiments are not limited thereto.

The first planarization layer 331 can be disposed on the first source electrode E1b and the first drain electrode E1c of the first transistor TFT1, and the second source electrode E2b and the second drain electrode E2c of the second transistor TFT2. The first planarization layer 331 can be disposed on the first transistor TFT1 and the second transistor TFT2. For example, the first planarization layer 331 can be disposed while covering both the first transistor TFT1 and the second transistor TFT2.

A relay electrode RE can be disposed on the first planarization layer 331. The relay electrode RE can electrically connect the second source electrode E2b of the second transistor TFT2 and the pixel electrode PE.

The relay electrode RE can be electrically connected to the second source electrode E2b of the second transistor TFT2 through the hole of the first planarization layer 331. The second source electrode E2b of the second transistor TFT2 can be electrically connected to the second capacitor electrode CAPE2 of the storage capacitor Cst.

The relay electrode RE can be disposed in the second metal layer on the first planarization layer 331 and can include a second metal. The second metal and the second metal layer can be referred to as a second source-drain metal and a second source-drain metal layer.

The second planarization layer 332 can be disposed on the relay electrode RE.

The light emitting element unit can be disposed on the second planarization layer 332. The light emitting element ED can be formed on the second planarization layer 332. The light emitting element ED can include a pixel electrode PE, an intermediate layer EL, and a common electrode CE. The emission area of the light emitting element ED can be formed in an area in which the pixel electrode PE, the intermediate layer EL, and the common electrode CE overlap each other.

The pixel electrode PE can be disposed on the second planarization layer 332. The pixel electrode PE can be electrically connected to the relay electrode RE through the hole of the second planarization layer 332.

A bank 333 can be disposed on the pixel electrode PE. The bank 333 can be disposed on the pixel electrode PE and a portion of the second planarization layer 332. The opening of the bank 333 can expose a portion of the pixel electrode PE to form the emission area. For example, the opening of the bank 333 can overlap a portion of the pixel electrode PE. For example, the bank 333 can be formed of a material including a black pigment, or an organic material such as a benzocyclobutene resin, an epoxy resin, a polyimide resin, an acrylic resin, or a photosensitive polymer, but embodiments of the disclosure are not limited thereto. When the bank 333 is formed of a material including a black pigment, a black dye, or the like, it can be a black bank. When the bank 333 is formed of a material including a black pigment or a black dye, light from the outside can be blocked or light reflected from the outside can be blocked, and thus the luminance of the display device can be further enhanced. A spacer can be disposed on the bank 333. The spacer can include an organic insulating material, but the embodiments of the disclosure are not limited thereto. The spacer can be formed of the same material as the bank 333, but embodiments of the disclosure are not limited thereto.

The intermediate layer EL of the light emitting element ED can be disposed on a portion of the pixel electrode PE and the bank 333. The common electrode CE can be disposed on the intermediate layer EL.

The encapsulation unit can be disposed on the light emitting element unit and can be positioned on the common electrode CE. The encapsulation unit can include the encapsulation layer 200 formed on the common electrode CE.

The encapsulation layer 200 can prevent moisture or oxygen from penetrating into the light emitting element ED. For example, the encapsulation layer 200 can prevent moisture or oxygen from penetrating into the organic material included in the intermediate layer EL of the light emitting element ED. The encapsulation layer 200 can be formed of a single layer or multiple layers, but embodiments of the disclosure are not limited thereto.

The encapsulation layer 200 can include a first encapsulation layer 341, a second encapsulation layer 342, and a third encapsulation layer 343, but embodiments of the disclosure are not limited thereto. For example, the first encapsulation layer 341 and the third encapsulation layer 343 can include an inorganic layer, and the second encapsulation layer 342 can include an organic layer, but embodiments of the disclosure are not limited thereto.

For example, the organic layer of the second encapsulation layer 342 can include an organic insulating material, such as acrylic resin, epoxy resin, polyimide, polyethylene and silicon oxycarbide (SiOC). The inorganic layer can include an inorganic insulating material. For example, the inorganic layers of the first encapsulation layer 341 and the third encapsulation layer 343 can include an inorganic insulating material capable of low-temperature deposition, such as silicon nitride (SiN), silicon oxide (SiO), silicon oxynitride (SiON) and aluminum oxide (Al₂O₃), without being limited thereto.

The display panel 110 according to example embodiments of the disclosure can have a built-in touch sensor, but embodiments of the disclosure are not limited thereto. In this case, the display panel 110 according to example embodiments of the disclosure can include a touch sensor layer 210 formed on the encapsulation layer 200.

The touch sensor layer 210 can include a plurality of touch electrodes TE, and can include a sensor metal TSM and a bridge metal BRG to form the plurality of touch electrodes TE. In embodiments of the disclosure, the sensor metal TSM can be referred to as a sensor metal layer TSM, and the bridge metal BRG can be referred to as a bridge metal layer BRG.

The touch sensor layer 210 can further include insulation layers such as a touch buffer layer 351 on the encapsulation layer 200, a touch interlayer insulation layer 352 on the touch buffer layer 351, and a touch protective layer 353 on the touch interlayer insulation layer 352. Here, the touch buffer layer 351 can be omitted.

The bridge metal BRG can be disposed between the touch buffer layer 351 and the touch interlayer insulation layer 352. The sensor metal TSM can be disposed between the touch interlayer insulation layer 352 and the touch protective layer 353.

Each of the plurality of touch electrodes TE can be formed of a sensor metal TSM. Each of the plurality of touch electrodes TE can be a mesh-type electrode having a plurality of openings.

The plurality of touch electrodes TE can include a first touch electrode TE1 and a second touch electrode TE2. The sensor metal TSM included in the first touch electrode TE1 can be electrically connected through the bridge metal BRG. For example, the sensor metals TSM spaced apart from each other can be electrically connected by the bridge metal BRG to constitute one first touch electrode TE1.

The bridge metal BRG can be disposed on the touch buffer layer 351. The touch interlayer insulation layer 352 can be disposed on the bridge layers BRG. For example, the touch interlayer insulation layer 352 can be disposed on the bridge layers BRG and a portion of the touch buffer layer 351. The sensor metal TSM can be disposed on the touch interlayer insulation layer 352. A portion of the sensor metal TSM can be connected to the corresponding bridge metal BRG through the hole of the touch interlayer insulation layer 352.

The sensor metal TSM and the bridge metal BRG can be disposed not to overlap the light emitting element ED. The sensor metal TSM and the bridge metal BRG can overlap the bank 333.

The plurality of sensor metals TSM can configure one touch electrode and can be disposed in a mesh form and electrically connected. A portion of the sensor metal TSM and another portion of the sensor metal TSM can be electrically connected through the bridge metal BRG to constitute one touch electrode TE. For example, the portion of the sensor metal TSM and another portion of the sensor metal TSM can be electrically connected through the bridge metal BRG to constitute the first touch electrode TE1.

The touch protective layer 353 can be disposed to cover the sensor metal TSM and the bridge metal BRG. For example, the touch protective layer 353 can be disposed to cover the sensor metal TSM and a portion of the touch interlayer insulation layer 352.

The touch line TL can electrically connect the touch electrode TE and the touch pad TP. The touch line TL can be formed of at least one of the sensor metal TSM and the bridge metal BRG.

When the display panel 110 is of a type in which the touch sensor is embedded, the touch line TL can extend along the outer inclined surface SLP_ENCAP of the encapsulation layer 200 and can extend beyond the upper portion of the dam DAM to the touch pad TP in the non-active area NA, but embodiments of the disclosure are not limited thereto.

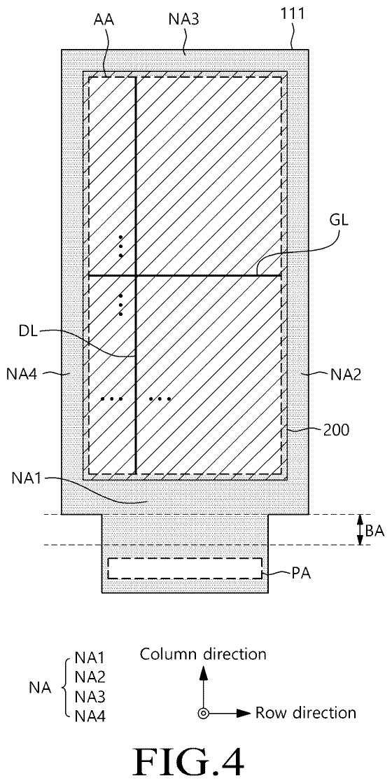

FIG. 4 illustrates a substrate 111 of a display panel 110 according to example embodiments of the disclosure.

Referring to FIG. 4, the substrate 111 of the display panel 110 according to example embodiments of the disclosure can include an active area AA in which an image can be displayed and a non-active area NA in which an image is not displayed.

The non-active area NA can include a plurality of non-active areas, such as a first non-active area NA1, a second non-active area NA2, a third non-active area NA3, and a fourth non-active area NA4, and so on.

The first non-active area NA1 can be positioned in the column direction from the active area AA. The second non-active area NA2 can be positioned in the row direction from the active area AA. The third non-active area NA3 can be positioned in the column direction from the active area AA and opposite to the first non-active area NA1. The fourth non-active area NA4 can be positioned in the row direction from the active area AA and opposite to the second non-active area NA2.

For example, the column direction can be a direction in which data lines DL are disposed to extend, and the row direction can be a direction in which gate lines GL are disposed to extend. As another example, the column direction can be a direction in which gate lines GL are disposed to extend, and the row direction can be a direction in which data lines DL are disposed to extend. The column direction and the row direction can be relative directions. For example, the column direction can be the row direction depending on the viewpoint, and the row direction can be the column direction depending on the viewpoint. For convenience of description, described below is an example in which each of the plurality of data lines DL is disposed in the column direction, and each of the plurality of gate lines GL is disposed in the row direction, but embodiments of the disclosure are not limited thereto.

The first non-active area NA1 can include a pad area PA in which a plurality of pads to which at least one driving circuit or printed circuit board is electrically connected are disposed. For example, a plurality of data lines DL, a first common driving voltage line VDDL, a second common driving voltage line VSSL, and the like can be electrically connected to the plurality of pads.

The first non-active area NA1 can further include a bending area BA. In this case, the substrate 111 can be a flexible substrate. In some cases, the first non-active area NA1 may not include the bending area BA. For example, the flexible substrate can be made of any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS), which is only an example and is not necessarily limited thereto.

The display panel 110 can further include a ground line disposed in the non-active area NA of the substrate 111. The ground line can be disposed from one point of the pad area PA to another point of the pad area PA via the second non-active area NA2, the third non-active area NA3, and the fourth non-active area NA4.

In the display panel 110 according to example embodiments of the disclosure, the encapsulation layer 200 can have a structure in which an inorganic film and an organic film are stacked, but embodiments of the disclosure are not limited thereto. In this case, an edge of the encapsulation layer 200 can be an edge of the organic film. The encapsulation layer 200 can extend from the active area AA to a portion of the non-active area NA.

The display panel 110 according to example embodiments of the disclosure can include at least one dam or at least one stopper positioned further outside than the organic film included in the encapsulation layer 200 to prevent overflow of the organic film included in the encapsulation layer 200. The at least one dam or the at least one stopper can include an organic film, but embodiments of the disclosure are not limited thereto.

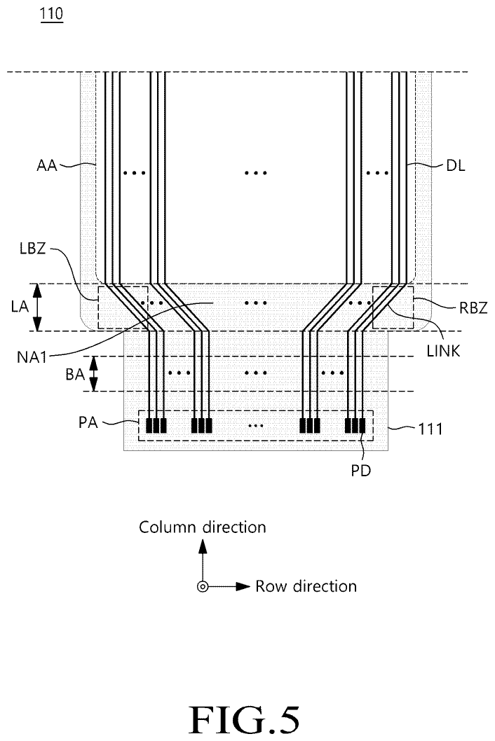

FIG. 5 is a plan view illustrating a display panel 110 according to example embodiments of the disclosure, and is a plan view illustrating a display panel 110 having a data link structure.

Referring to FIG. 5, the display panel 110 according to example embodiments of the disclosure can include a plurality of data lines DL for supplying a data voltage VDATA and a plurality of pads PD disposed in a pad area PA and electrically connected to a data driving circuit 120.

The display panel 110 according to example embodiments of the disclosure can include a data link structure for electrically connecting the plurality of data lines DL and the plurality of pads PD. The data link structure according to example embodiments of the disclosure can include a plurality of data link lines LINK.

The plurality of data link lines LINK can be disposed in the non-active area NA. For example, the plurality of data link lines LINK can be disposed in the first non-active area NA1 including the pad area PA. The plurality of data link lines LINK can be electrically connected to the plurality of data lines DL in the active area AA.

In addition to the pad area PA and the bending area BA, the first non-active area NA1 can further include a link area LA.

For example, each of the plurality of data link lines LINK can be disposed over the pad area PA, the bending area BA, and the link area LA. Each of the plurality of data link lines LINK can include a first end (or a first side) electrically connected to the pad PD disposed in the pad area PA and a second end (or a second side) electrically connected to the data line DL disposed in the active area AA. A line portion between two opposite ends (the first end and the second end, or the first side and the second side) of each of the plurality of data link lines LINK can be disposed over the bending area BA and the link area LA.

For example, each of the plurality of data link lines LINK can be formed of a single line or two or more lines, but embodiments of the disclosure are not limited thereto. Each of the plurality of data link lines LINK can be disposed on one metal layer or can be disposed on two or more metal layers.

The bending area BA can be bent during manufacturing of the display panel 110. Accordingly, when the user views the display device 100 from the front, the bending area BA and the pad area PA are not visible from the front.

However, when the user views the display device 100 from the front, the link area LA can be recognized as a bezel even if it is covered by a case. Accordingly, in order to implement a narrow bezel, it can be necessary to reduce the area of the link area LA.

Since all of the plurality of data link lines LINK must be electrically connected to the plurality of data lines DL in the link area LA in the first non-active area NA1, the area of the link area LA is inevitably increased.

For example, when the length of the pad area PA in the row direction is shorter than the length of the active area AA in the row direction, each of the plurality of data link lines LINK in the left and right areas LBZ and RBZ in the link area LA should be electrically connected to the plurality of data lines DL while extending in the diagonal direction. Therefore, the length of the link area LA in the column direction is inevitably increased, and the area of the link area LA is inevitably increased.

Accordingly, as illustrated in FIG. 5, when the display panel 110 has a data link structure in which a plurality of data link lines LINK are disposed in the first non-active area NA1, the area of the link area LA in the first non-active area NA1 can increase. When the user views the display device 100 from the front, the link area LA can be recognized as a large bezel.

Therefore, in order to implement a narrow bezel, a data link structure capable of reducing the area of the link area LA is required. Accordingly, embodiments of the disclosure propose a data link structure capable of implementing a narrow bezel.

Hereinafter, a data link structure capable of implementing a narrow bezel according to example embodiments of the disclosure is described.

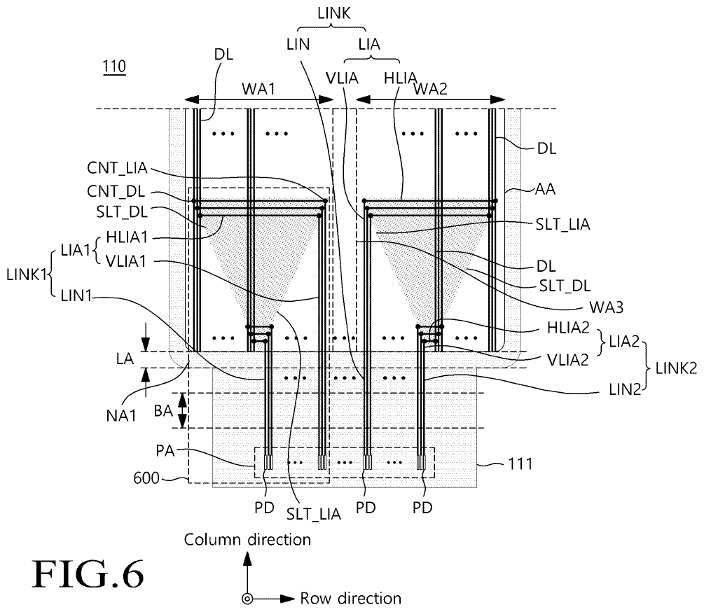

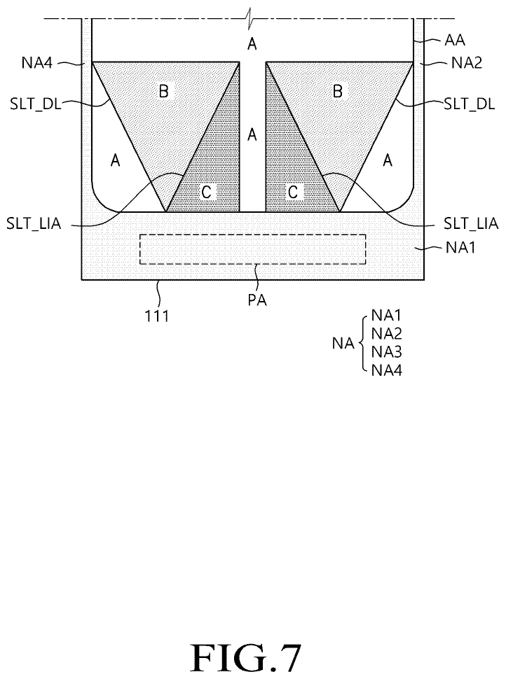

FIG. 6 is a plan view illustrating a display panel 110 according to example embodiments of the disclosure, and is a plan view illustrating a display panel 110 having a data link structure. FIG. 7 illustrates three areas A, B, and C distinguished within an active area AA by a data link structure of a display panel 110 according to example embodiments of the disclosure. The data link structure according to the disclosure can be a bezel-reduced data link structure.

Referring to FIG. 6, the non-active area NA can include a first non-active area NA1 positioned in the column direction from the active area AA. The first non-active area NA1 can include a pad area PA and a link area LA positioned in the column direction from the active area AA.

The display panel 110 according to example embodiments of the disclosure can include a data link structure capable of reducing the bezel while supplying the data voltage VDATA to the plurality of subpixels SP disposed in the active area AA.

A data link structure according to example embodiments of the disclosure can include a plurality of data link lines LINKs that electrically connect the plurality of data lines DL and the plurality of pads PD.

The plurality of data lines DL can be disposed in the active area AA and each can extend in the column direction, and can be connected to the plurality of subpixels SP disposed in the active area AA.

The plurality of pads PD can be disposed in the pad area PA included in the first non-active area NA1.

The plurality of data link lines LINK can electrically connect the plurality of pads PD disposed in the pad area PA included in the first non-active area NA1 and the plurality of data lines DL disposed in the active area AA.

Each of the plurality of data link lines LINK included in the data link structure for the narrow bezel according to example embodiments of the disclosure can include a portion LIA disposed in the active area AA.

According to the data link structure according to the embodiments of the disclosure, the plurality of data link lines LINK and the plurality of data lines DL can be electrically connected within the active area AA. For example, in the bezel-reduced data link structure according to example embodiments of the disclosure, the data line connection hole CNT_DL between the plurality of data link lines LINK and the plurality of data lines DL can be positioned in the active area AA.

Accordingly, each of the plurality of data link lines LINK does not need to extend in the diagonal direction from the left and right areas in the link area LA, and each of the plurality of data link lines LINK can enter the active area AA by passing the link area LA within a short distance in the column direction and be connected to the data line DL in the active area AA.

Since the display panel 110 according to example embodiments of the disclosure has a bezel-reduced data link structure, the length of the link area LA in the column direction can be very short or zero. Accordingly, the first non-active area NA1 that the user can see from the front can be very small.

In the data link structure according to example embodiments of the disclosure, each of the plurality of data link lines LINK can include a data link line LIA disposed in the active area AA.

The data link line LIA of the active area AA can include a first data link line HLIA disposed in the active area AA and extending in a first direction and a second data link line VLIA disposed in the active area AA and extending in a second direction.

Hereinafter, for convenience of description, the first direction can be described as a row direction (a horizontal direction), the second direction can be described as a column direction (a vertical direction), the first data link line HLIA can be described as a “horizontal data link line”, and the second data link line VLIA can be described as a “vertical data link line”. The data link line LIA of the active area AA can be simply abbreviated as the data link line LIA. However, the present embodiments are not limited thereto.

The vertical data link line VLIA can electrically connect the pad PD and the horizontal data link line HLIA. The horizontal data link line HLIA can electrically connect the vertical data link line VLIA and the data line DL.

The horizontal data link line HLIA and the vertical data link line VLIA can be electrically connected in the link line connection hole CNT_LIA. The horizontal data link line HLIA and the data line DL can be electrically connected in the data line connection hole CNT_DL.

Each of the plurality of data link lines LINK can further include a data link line LIN of the non-active area disposed in the first non-active area NA1 included in the non-active area NA.

The non-active data link line LIN can be integrated with the vertical data link line VLIA. Alternatively, the non-active data link line LIN can be a line electrically connected to the vertical data link line VLIA but disposed on a metal layer different from the vertical data link line VLIA. Alternatively, the non-active data link line LIN can include a line electrically connected to the vertical data link line VLIA but disposed on a metal layer different from the vertical data link line VLIA.

When the display panel 110 according to example embodiments of the disclosure has the data link structure as shown in FIG. 6, the horizontal data link line HLIA included in each of the plurality of data link lines LINK can be disposed in the active area AA and can be parallel to the plurality of gate lines GL each extending in the row direction (horizontal direction).

Further, when the display panel 110 according to example embodiments of the disclosure has the data link structure as shown in FIG. 6, the horizontal data link line HLIA included in each of the plurality of data link lines LINK can overlap at least one gate line GL in the vertical direction.

Among the plurality of vertical data link lines VLIA, the vertical data link line VLIA electrically connected to the data line DL positioned further inside can have a shorter length. Among the plurality of vertical data link lines VLIA, the vertical data link line VLIA electrically connected to the data line DL positioned further outside can have a longer length. The length of the vertical data link line VLIA electrically connected to the data line DL positioned further inside among the plurality of vertical data link lines VLIA can be shorter than the length of the vertical data link line VLIA electrically connected to the data line DL positioned further outside among the plurality of vertical data link lines VLIA.

Among the plurality of horizontal data link lines HLIA, the horizontal data link line HLIA electrically connected to the data line DL positioned further inside can have a shorter length. Among the plurality of horizontal data link lines HLIA, the horizontal data link line HLIA electrically connected to the data line DL positioned further outside can have a longer length. The horizontal data link line HLIA electrically connected to the data line DL positioned further inside among the plurality of horizontal data link lines HLIA can be shorter than the horizontal data link line HLIA electrically connected to the data line DL positioned further outside among the plurality of horizontal data link lines HLIA.

Among the plurality of horizontal data link lines HLIA, the length of the horizontal data link line HLIA close to the pad area PA can be short. Among the plurality of horizontal data link lines HLIA, the length of the horizontal data link lines HLIA positioned further away from the pad area PA can be longer. The length of the horizontal data link line HLIA close to the pad area PA among the plurality of horizontal data link lines HLIA can be shorter than the length of the horizontal data link line HLIA positioned further away from the pad area PA among the plurality of horizontal data link lines HLIA.

The first link line LINK1 can include the data link line LIA1 of the active area and the data link line LIN1 of the non-active area. The data link line LIA1 of the active area can include a first horizontal data link line HLIA1 and a first vertical data link line VLIA1.

The second link line LINK2 can include the data link line LIA2 of the active area and the data link line LIN2 of the non-active area. The data link line LIA2 of the active area can include a second horizontal data link line HLIA2 and a second vertical data link line VLIA2.

The length of the first vertical data link line VLIA1, of the first vertical data link line VLIA1 and the second vertical data link line VLIA2, electrically connected to the first data line DL1 positioned further outside, of the first data line DL1 and the second data line DL2 can be longer than the length of the second vertical data link line VLIA2.

The length of the first horizontal data link line HLIA1, of the first horizontal data link line HLIA1 and the second horizontal data link line HLIA2, electrically connected to the first data line DL1 positioned further outside, of the first data line DL1 and the second data line DL2, can be longer than the length of the second horizontal data link line HLIA2.

Because the length of the first horizontal data link line HLIA1 is longer than the length of the second horizontal data link line HLIA2, a first area in which the first horizontal data link line HLIA1 overlaps at least one gate line GL can be larger than a second area in which the second horizontal data link line HLIA2 overlaps at least one gate line GL.

As illustrated in FIG. 6, the points CNT_DL where the data lines DL and the horizontal data link lines HLIA are connected can form two first slant lines SLT_DL. Further, the points CNT_LIA where the vertical data link lines VLIA and the horizontal data link lines HLIA are connected can form two second slant lines SLT_LIA.

Two triangles can be formed by the two first slant lines SLT_DL and the two second slant lines SLT_LIA. In each of the two triangles, one of the three sides can be a horizontal side parallel to the horizontal data link lines HLIA, and the vertex facing the horizontal side can be positioned at or near a boundary point between the active area AA and the first non-active area NA1.

For example, the active area AA can include a plurality of line areas, such as a first line area WA1, a second line area WA2, and a third line area WA3, and so on. The third line area WA3 can be positioned between the first line area WA1 and the second line area WA2. Alternatively, the active area AA can include a plurality of areas, such as a first line area WA1, a second line area WA2.

The first line area WA1 and the second line area WA2 can have the same line arrangement structure. The third line area WA3 can have a line arrangement structure different from that of the first line area WA1 and the second line area WA2, without being limited thereto.

The first line area WA1 and the second line area WA2 can be areas in which the data lines DL and the data link lines LIA are disposed. The third line area WA3 can be an area in which the data lines DL are disposed but the data link lines LIA are not disposed. In this case, some of the data lines DL can receive the data voltage VDATA through the data link lines LIA.

As another example, the active area AA can include a first line area WA1 and a second line area WA2, but may not include a third line area WA3. Accordingly, the first line area WA1 and the second line area WA2 can contact each other. The first line area WA1 and the second line area WA2 can be areas in which the data lines DL and the data link lines LIA are disposed. In this case, all of the data lines DL can receive the data voltage VDATA through the data link lines LIA.

When the display panel 110 according to example embodiments of the disclosure has the data link structure as shown in FIG. 6, the horizontal data link line HLIA included in each of the plurality of data link lines LINK can be parallel to the plurality of gate lines GL disposed in the active area AA and each extending in the row direction (horizontal direction), and the horizontal data link line HLIA included in each of the plurality of data link lines LINK can overlap at least one gate line GL in the vertical direction.

Referring to FIG. 7, according to the data link structure, the active area AA can include three areas A, B, and C.

The first area A can be an area in which a data link structure is not disposed. For example, the first area A can be an area in which the horizontal data link lines HLIA and the vertical data link lines VLIA are not disposed. The second area B and the third area C can be areas in which a data link structure is disposed. The second area B can be an area in which the horizontal data link lines HLIA are disposed. The third area C can be an area in which the vertical data link lines VLIA are disposed. The data link structure can be a bezel-reduced data link structure.

Among the first to fourth non-active areas NA1 to NA4 included in the non-active area NA, the first non-active area NA1 including the pad area PA can contact one side of each third area C. Also, the first non-active area NA1 including the pad area PA can contact one side of each first area A.

The second area B can have an inverted triangle shape or an isosceles triangle shape. The active area AA can include two second areas B. The two second areas B can be positioned on two opposite sides of the first area A positioned in the middle.

The third area C can have a right triangle shape. The active area AA can include two third areas C. The two third areas C can be positioned on two opposite sides of the first area A positioned in the middle.

A first portion of first area A can be positioned at an upper end (or an upper side) of the two second areas B, a second portion of first area A can be positioned between the two third areas C, or a third portion of first area A can be positioned outside each of the two second areas B. The first area A positioned between the two third areas C can correspond to the third line area WA3 of FIG. 6.

Referring to FIGS. 6 and 7, the boundary between the first area A and the second area B can correspond to the points CNT_DL where the horizontal data link lines HLIA and the data lines DL are connected, and can form the first slant line SLT_DL.

The boundary between the second area B and the third area C can be points CNT_LIA where the vertical data link lines VLIA and the horizontal data link lines HLIA are connected, and can form the second slant line SLT_LIA.

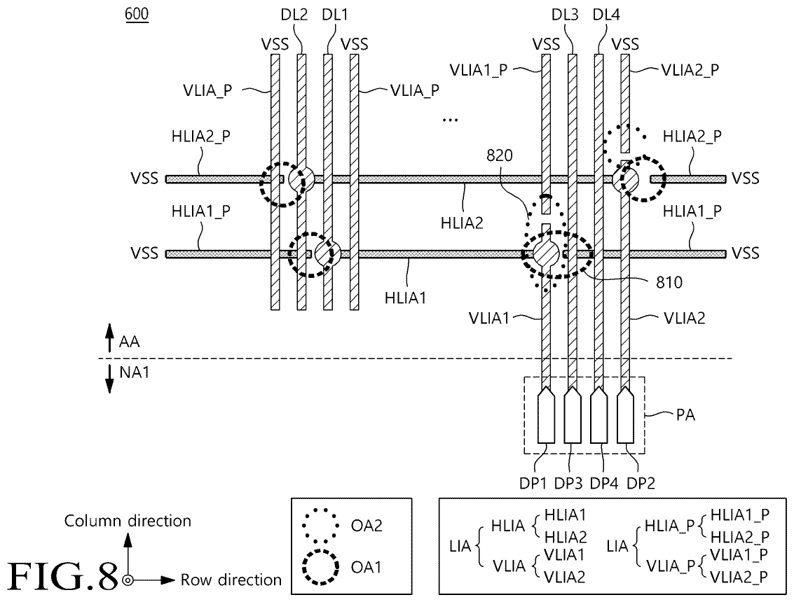

FIG. 8 is a plan view illustrating a display panel 110 having a data link structure according to example embodiments of the disclosure. In the following description, FIG. 6 is also referred to.

The first non-active area NA1 can include a pad area PA in which a plurality of data pads are disposed.

Referring to FIG. 8, the first non-active area NA1 can include a pad area PA in which a plurality of data pads DP1 to DP4 are disposed. The plurality of data pads DP1 to DP4 can include a first data pad DP1, a second data pad DP2, a third data pad DP3, and a fourth data pad DP4.

The plurality of data lines DL can be disposed in the active area AA and can include a plurality of data lines. For example, the plurality of data lines can include a first data line DL1, a second data line DL2, a third data line DL3, and a fourth data line DL4. Each of the first data line DL1, the second data line DL2, the third data line DL3, and the fourth data line DL4 can be disposed in the active area AA, extend in the column direction, and receive a data voltage, without being limited thereto.

A data link structure is disposed in the active area AA adjacent to the first non-active area NAL. The data link structure can be a bezel-reduced data link structure.

The data link structure can include data link lines LIA of the active area. The data link lines LIA of the active area can include horizontal data link lines HLIA and vertical data link lines VLIA.

Each of the horizontal data link lines HLIA can be disposed in the active area AA. The whole or part of each of the vertical data link lines VLIA can be disposed in the active area AA.

The horizontal data link lines HLIA can be electrically connected to the first data line DL1. The horizontal data link lines HLIA can be disposed in the active area AA. The horizontal data link lines HLIA can extend in the row direction. The horizontal data link lines HLIA can include a first horizontal data link line HLIA1 positioned in the first metal layer ML1.

The vertical data link lines VLIA can electrically connect the first horizontal data link line HLIA1 and the first data pad DPL. The vertical data link lines VLIA can extend in the column direction. The vertical data link lines VLIA can include a first vertical data link line VLIA1 positioned in a second metal layer ML2 different from the first metal layer ML1. The whole or part of the first vertical data link line VLIA1 can be disposed in the active area AA.

The horizontal data link lines HLIA can be electrically connected to the second data line DL2. The horizontal data link lines HLIA can be disposed in the active area AA. The horizontal data link lines HLIA can extend in the row direction. The horizontal data link lines HLIA can further include a second horizontal data link line HLIA2 positioned in the first metal layer ML1.

The vertical data link lines VLIA can electrically connect the second horizontal data link line HLIA2 and the second data pad DP2. The vertical data link lines VLIA can extend in the column direction. The vertical data link lines VLIA can further include a second vertical data link line VLIA2 positioned in the second metal layer ML2 different from the first metal layer ML1. The whole or part of the second vertical data link line VLIA2 can be disposed in the active area AA.

The display panel 110 according to example embodiments of the disclosure can include a plurality of power lines LIA_P disposed in the active area AA. The plurality of power lines LIA_P can include a plurality of first power lines HLIA_P each extending in the first direction and a plurality of second power lines VLIA_P each extending in the second direction.

Hereinafter, for convenience of description, the first direction can be described as a row direction, the second direction can be described as a column direction, the first power line HLIA_P can be described as a “horizontal power line HLIA_P”, and the second power line VLIA_P can be described as a “vertical power line VLIA_P”. However, the present embodiments are not limited thereto.

The horizontal power line HLIA_P can be spaced apart from the horizontal data link line HLIA to extend in the row direction and can be positioned in the first metal layer ML1. The vertical power line VLIA_P can be spaced apart from the vertical data link line VLIA to extend in the column direction and can be positioned in the second metal layer ML2.

The horizontal power line HLIA_P can include a first horizontal power line HLIA1_P. The first horizontal power line HLIA1_P can be spaced apart from the first horizontal data link line HLIA1 and extend in the row direction, and can be positioned in the first metal layer ML1.

The horizontal power line HLIA_P can include a second horizontal power line HLIA2_P. The second horizontal power line HLIA2_P can be spaced apart from the second horizontal data link line HLIA2 and extend in the row direction, and can be positioned in the first metal layer ML1.

The vertical power line VLIA_P can include a first vertical power line VLIA1_P. The first vertical power line VLIA1_P can be spaced apart from the first vertical data link line VLIA1 and extend in the column direction, and can be positioned in the second metal layer ML2.

The vertical power line VLIA_P can include a second vertical power line VLIA2_P. The second vertical power line VLIA2_P can be spaced apart from the second vertical data link line VLIA2 and extend in the column direction, and can be positioned in the second metal layer ML2.

If the first and second horizontal power lines HLIA1_P and HLIA2_P are not disposed in the area in which the first and second horizontal power lines HLIA1_P and HLIA2_P are disposed, an imbalance in the presence of the first metal layer between the area in which the first and second horizontal data link lines HLIA1 and HLIA2 are disposed and the area in which the first and second horizontal data link lines HLIA1 and HLIA2 are not disposed can occur. For this reason, a large deviation in light reflection characteristics for each position can occur inside the display panel 110, resulting in an image abnormality and an appearance abnormality. The light can include at least one of internal light emitted from the light emitting element ED and external light introduced into the display panel 110 from the outside.

Further, when the first and second vertical power lines VLIA1_P and VLIA2_P are not disposed in the area in which the first and second vertical power lines VLIA1_P and VLIA2_P are disposed, an imbalance in the presence of the second metal layer between the area in which the first and second vertical data link lines VLIA1 and VLIA2 are disposed and the area in which the first and second vertical data link lines VLIA1 and VLIA2 are not disposed can occur. Accordingly, a large deviation in light reflection characteristics for each position can occur inside the display panel 110, resulting in an image abnormality and an appearance abnormality. The light can include at least one of internal light emitted from the light emitting element ED and external light introduced into the display panel 110 from the outside.

For example, it is possible to reduce image and appearance abnormalities due to imbalance of the metal layer through the first and second horizontal power lines HLIA1_P and HLIA2_P and the first and second vertical power lines VLIA1_P and VLIA2_P.

The common driving voltage, which is a power voltage transferred by the horizontal power line HLIA_P and the vertical power line VLIA_P, can be one of the first common driving voltage VDD and the second common driving voltage VSS. However, the common driving voltage transferred by the horizontal power line HLIA_P and the vertical power line VLIA_P is not limited thereto, and any direct current (DC) power voltage in which the level of the voltage supplied to the display panel 110 is constant can be possible.

In embodiments of the disclosure, for convenience of description, an example is described in which the common driving voltage transferred by the horizontal power line HLIA_P and the vertical power line VLIA_P is the second common driving voltage VSS applied to the common electrode CE. The second common driving voltage VSS is also referred to as a base voltage or a low-potential power voltage.

The plurality of horizontal power lines HLIA_P and the plurality of vertical power lines VLIA_P included in the plurality of power lines LIA_P can be arranged (configured) in a mesh form. Accordingly, the area in which the base voltage VSS, which is the second common driving voltage, is transferred through the horizontal power line HLIA_P and the vertical power line VLIA_P can be increased, and the transfer characteristic of the base voltage VSS can be greatly enhanced.

In the same first row, as the same horizontal metal pattern (metal pattern of the first metal layer) is disposed to be separated into the first horizontal data link line HLIA1 and the first horizontal power line HLIA1_P, in the same first column, the same vertical metal pattern (metal pattern of the second metal layer) is disposed to be separated into the first vertical data link line VLIA1 and the first vertical power line VLIA1_P, in the same second row, the same horizontal metal pattern (metal pattern of the first metal layer) is disposed to be separated into the second horizontal data link line HLIA2 and the second horizontal power line HLIA2_P, and in the same second column, the vertical metal pattern (metal pattern of the second metal layer) is disposed to be separated into the second vertical data link line VLIA2 and the second vertical power line VLIA2_P, the length and area of the path through which the data voltage is transferred can be reduced. Accordingly, the parasitic capacitance related to the second data line DL2 can be reduced.

The horizontal power line HLIA_P and the vertical power line VLIA_P can be lines that transfer a common driving voltage for display driving.

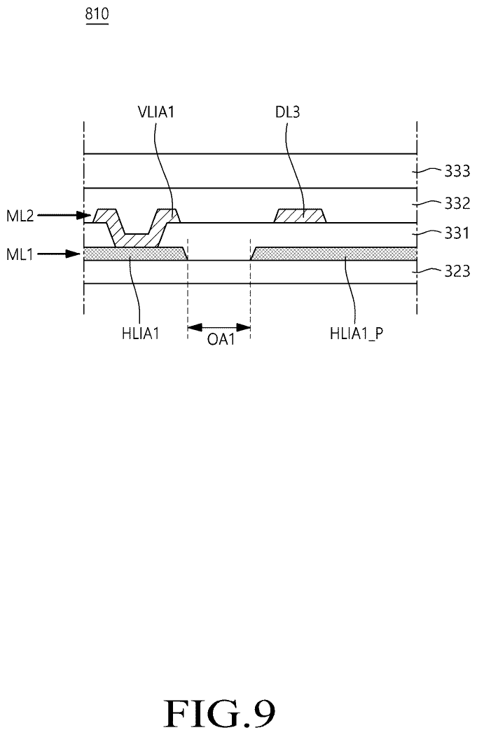

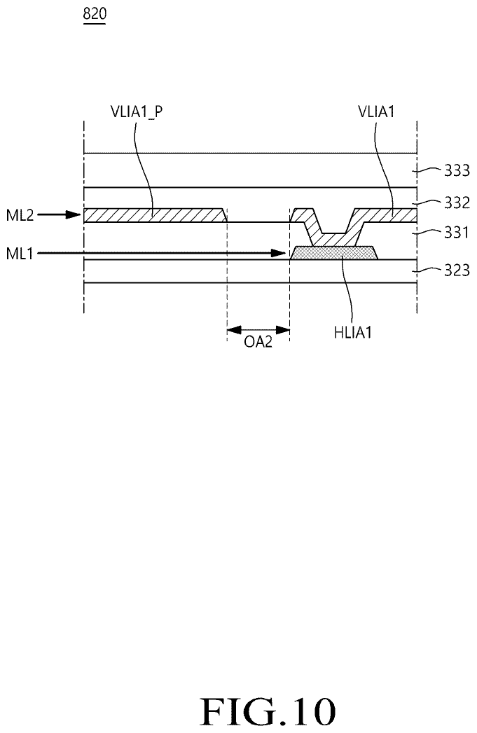

FIGS. 9 and 10 are cross-sectional views illustrating a display panel 110 having a data link structure according to example embodiments of the disclosure. In the following description, FIGS. 6 and 8 are also referred to.

Referring to FIG. 9, the first horizontal data link line HLIA1 and the first horizontal power line HLIA1_P can be disposed on the second interlayer insulation layer 323. For example, the first horizontal data link line HLIA1 and the first horizontal power line HLIA1_P can be disposed on a portion of the second interlayer insulation layer 323. The first horizontal data link line HLIA1 and the first horizontal power line HLIA1_P can be disposed to be spaced apart from each other. Specifically, a first open area OA1 can be disposed between the first horizontal data link line HLIA1 and the first horizontal power line HLIA1_P.

The first planarization layer 331 can be disposed on the first horizontal data link line HLIA1 and the first horizontal power line HLIA1_P. Specifically, the first planarization layer 331 can be disposed on a portion of the first horizontal data link line HLIA1 and the first horizontal power line HLIA1_P and a portion of the second interlayer insulation layer 323.

The first vertical data link line VLIA1 and another vertical line (e.g., the data line DL3) can be disposed on the first planarization layer 331.

The first vertical data link line VLIA1 can be connected to the first horizontal data link line HLIA1 through a hole passing through the first planarization layer 331.

The second planarization layer 332 can be disposed on the first vertical data link line VLIA1 and another vertical line (e.g., the data line DL3). The bank 333 can be disposed on the second planarization layer 332.

The metal layer where the first horizontal data link line HLIA1 and the first horizontal power line HLIA1_P are disposed can be the first metal layer ML1 between the second interlayer insulation layer 323 and the first planarization layer 331.

The separation space between the first horizontal data link line HLIA1 and the first horizontal power line HLIA1_P in the first metal layer ML1 can be referred to as a first open area OA1 of the first metal layer MLL.

The metal layer where the first vertical data link line VLIA1 and another vertical line (e.g., the data line DL3) are disposed can be the second metal layer ML2 between the first planarization layer 331 and the second planarization layer 332.

Referring to FIG. 10, the first horizontal data link line HLIA1 can be disposed on the second interlayer insulation layer 323.

The first planarization layer 331 can be disposed on the first horizontal data link line HLIA1. Specifically, the first planarization layer 331 can be disposed on the first horizontal data link line HLIA1 and a portion of the second interlayer insulation layer 323.

The first vertical data link line VLIA1 and the first vertical power line VLIA1_P can be disposed to be spaced apart from each other on the first planarization layer 331.

The first vertical data link line VLIA1 can be connected to the first horizontal data link line HLIA1 through a hole passing through the first planarization layer 331.

The second planarization layer 332 can be disposed on the first vertical data link line VLIA1 and the first vertical power line VLIA1_P. The bank 333 can be disposed on the second planarization layer 332. Specifically, the second planarization layer 332 can be disposed on the first vertical data link line VLIA1 and the first vertical power line VLIA1_P and a portion of the first planarization layer 331. The first vertical data link line VLIA1 and the first vertical power line VLIA1_P can be disposed to be spaced apart from each other.

The first vertical power line VLIA1_P can be disposed in the second metal layer ML2 together with the first vertical data link line VLIA1.

The separation space between the first vertical data link line VLIA1 and the first vertical power line VLIA1_P in the second metal layer ML2 can be referred to as a second open area OA2 of the second metal layer ML2.

As described above, the common driving voltage required for display driving can be transferred through the horizontal power lines HLIA1_P and HLIA2_P spaced apart from the horizontal data link lines HLIA1 and HLIA2 and the vertical power lines VLIA1_P and VLIA2_P spaced apart from the vertical data link lines VLIA1 and VLIA2. For example, the common driving voltage can be the base voltage VSS.

Accordingly, the path through which the common driving voltage is transferred can be configured in a mesh form. Accordingly, the area in which the common driving voltage is transferred can be increased, and the transfer characteristic of the common driving voltage can be greatly enhanced.

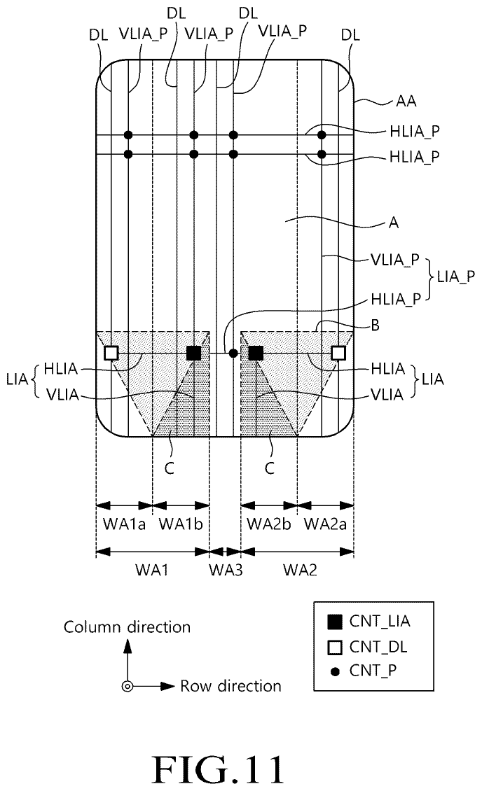

Hereinafter, a power line structure for transferring a power voltage input to the display panel 110 by the power supply circuit to the display driving electrode is described in more detail with reference to FIGS. 11 to 20. In the following description, an example is described in which the display driving electrode is the common electrode CE, and the power voltage is the second common driving voltage VSS applied to the common electrode CE. However, embodiments of the disclosure are not limited thereto.

FIG. 11 is a plan view illustrating an active area AA of a display panel 110 having a power line structure associated with a data link structure according to example embodiments of the disclosure.

Referring to FIG. 11, in the display panel 110 according to example embodiments of the disclosure, the active area AA can include a bezel-reduced data link structure.

The bezel-reduced data link structure can include a plurality of data link lines LIA disposed in the active area AA. The plurality of data link lines LIA can be electrically connected to the plurality of data lines DL, and can transfer the data voltage VDATA to the plurality of data lines DL.

The plurality of data link lines LIA can include a plurality of vertical data link lines VLIA and a plurality of horizontal data link lines HLIA. Each of the plurality of vertical data link lines VLIA can extend in the column direction, and each of the plurality of horizontal data link lines HLIA can extend in the row direction.

The horizontal data link line HLIA and the vertical data link line VLIA can be electrically connected in the link line connection hole CNT_LIA, and the horizontal data link line HLIA and the data line DL can be electrically connected in the data line connection hole CNT_DL.

The vertical data link line VLIA can electrically connect the data pad and the horizontal data link line HLIA. The horizontal data link line HLIA can electrically connect the vertical data link line VLIA and the data line DL. Accordingly, the data voltage VDATA output from the data driving circuit 120 can be transferred to the data line DL through the vertical data link line VLIA and the horizontal data link line HLIA.

At least one of the plurality of data lines DL can be directly supplied with the data voltage VDATA through the data link line LIN disposed in the non-active area NA, without passing through the data link line LIA disposed in the active area AA.

In the display panel 110 according to example embodiments of the disclosure, the active area AA can include a power line structure associated with a bezel-reduced data link structure.

The power line structure can include a plurality of power lines LIA_P disposed in the active area AA and transferring power voltages to the plurality of subpixels SP. The power voltage can be the second common driving voltage VSS applied to the common electrode CE.

The plurality of power lines LIA_P can include a plurality of vertical power lines VLIA_P and a plurality of horizontal power lines HLIA_P. Each of the plurality of vertical power lines VLIA_P can extend in the column direction, and each of the plurality of horizontal power lines HLIA_P can extend in the row direction.

The plurality of vertical power lines VLIA_P and the plurality of horizontal power lines HLIA_P can be electrically connected to each other. At least one of the plurality of vertical power lines VLIA_P can be electrically connected to at least one horizontal power line HLIA_P through the power connection hole CNT_P. The power connection hole CNT_P can be a contact hole disposed in the active area AA.

The power line structure according to example embodiments of the disclosure can be configured in association with the bezel-reduced data link structure.

The plurality of horizontal power lines HLIA_P can be disposed on the same metal layer (e.g., the first metal layer ML1 of FIGS. 9 and 10) as the plurality of horizontal data link lines HLIA, and the plurality of vertical power lines VLIA_P can be disposed on the same metal layer (e.g., the second metal layer ML2 of FIGS. 9 and 10) as the plurality of vertical data link lines VLIA.

The plurality of horizontal power lines HLIA_P can be formed together with the plurality of horizontal data link lines HLIA, and the plurality of vertical power lines VLIA_P can be formed together with the plurality of vertical data link lines VLIA.

At least one of the plurality of horizontal power lines HLIA_P can be disposed in the same row as the corresponding horizontal data link line HLIA to be spaced apart. The horizontal power line HLIA_P and the horizontal data link line HLIA spaced apart from each other in the same row can be first metal patterns disconnected in the first metal layer ML1. For example, a first open area can be disposed between the horizontal data link line HLIA and the horizontal power lines HLIA_P. At least one of the plurality of vertical power lines VLIA_P can be disposed in the same row as the corresponding vertical data link line VLIA and be spaced apart. The vertical power line VLIA_P and the vertical data link line VLIA spaced apart from each other in the same row can be second metal patterns disconnected in the second metal layer ML2. For example, a second open area can be disposed between the vertical data link line VLIA and the vertical power lines VLIA_P.

The active area AA can include a plurality of line areas, such as a first line area WA1, a second line area WA2, and a third line area WA3, and so on. The third line area WA3 can be positioned between the first line area WA1 and the second line area WA2. Alternatively, the active area AA can include a plurality of areas, such as a first line area WA1, a second line area WA2.

The first line area WA1 and the second line area WA2 can have the same line arrangement structure. The third line area WA3 can have a line arrangement structure different from that of the first line area WA1 and the second line area WA2, without being limited thereto.

The first line area WA1 and the second line area WA2 can be areas in which the data lines DL and the data link lines LIA are disposed.

Each of the first line area WA1 and the second line area WA2 can include a first area A, a second area B, and a third area C in the active area AA. The first area A can be an area in which the horizontal data link lines HLIA and the vertical data link lines VLIA are not disposed, the second area B can be an area in which the horizontal data link lines HLIA are disposed, and the third area C can be an area in which the vertical data link lines VLIA are disposed.

The third line area WA3 can be an area in which the data lines DL are disposed but the data link lines LIA are not disposed.

The third line area WA3 can include the first area A among the first area A, the second area B, and the third area C in the active area AA.

The first line area WA1 can include a first sub line area WA1a and a second sub line area WA1b.

The first sub line area WA1a can include data lines DL, data link lines LIA, and power lines LIA_P.

The data link lines LIA disposed in the first sub line area WA1a can include horizontal data link lines HLIA.

The horizontal data link lines HLIA disposed in the first sub line area WA1a can be connected to the vertical data link lines VLIA in the second sub line area WA1b to extend to the first sub line area WA1a.

The data lines DL disposed in the first sub line area WA1a can receive the data voltage VDATA through the horizontal data link lines HLIA.

The power lines LIA_P disposed in the first sub line area WA1a can include at least one vertical power line VLIA_P and at least one horizontal power line HLIA_P.

The vertical power line VLIA_P disposed in the first sub line area WA1a can have the length corresponding to the length in the column direction of the active area AA.

The horizontal power line HLIA_P disposed in the first sub line area WA1a can be disposed to be disconnected from the corresponding horizontal data link line HLIA disposed in the same row. Accordingly, the horizontal power line HLIA_P disposed in the first sub line area WA1a can have the length shorter than the length in the row direction of the active area AA.

The second sub line area WA1b can include a data line DL, data link lines LIA, and power lines LIA_P.

The data link lines LIA disposed in the second sub line area WA1b can include vertical data link lines VLIA and horizontal data link lines HLIA. In the second sub line area WA1b, the vertical data link lines VLIA and the horizontal data link lines HLIA can be connected to each other.

The data lines DL disposed in the second sub line area WA1b can be directly supplied with the data voltage VDATA through the data link line LIN disposed in the non-active area NA, without passing through the horizontal data link lines HLIA. The data line DL disposed in the second sub line area WA1b can have the length corresponding to the length in the column direction of the active area AA.

The power lines LIA_P disposed in the second sub line area WA1b can include vertical power lines VLIA_P and horizontal power lines HLIA_P.

The vertical power line VLIA_P disposed in the second sub line area WA1b can be disposed to be disconnected from the vertical data link line VLIA disposed in the same column. Accordingly, the vertical power line VLIA_P disposed in the second sub line area WA1b can have the length shorter than the length in the column direction of the active area AA. The vertical power lines VLIA_P disposed in the second sub line area WA1b can have different lengths.

The horizontal power line HLIA_P disposed in the second sub line area WA1b can be disposed to be disconnected from the corresponding horizontal data link line HLIA disposed in the same row. Accordingly, the horizontal power line HLIA_P disposed in the second sub line area WA1b can have the length shorter than the length in the row direction of the active area AA. The horizontal power lines HLIA_P disposed in the second sub line area WA1b can have different lengths.

The second line area WA2 can include a third sub line area WA2a and a fourth sub line area WA2b.

The third sub line area WA2a can include data lines DL, data link lines LIA, and power lines LIA_P. The third sub line area WA2a can have the same line structure (line arrangement structure) as the first sub line area WA1a. The line structure (line arrangement structure) of the third sub line area WA2a can be symmetrical to the line structure (line arrangement structure) of the first sub line area WA1a.

The fourth sub line area WA2b can include a data line DL, data link lines LIA, and power lines LIA_P. The fourth sub line area WA2b can have the same line structure (line arrangement structure) as the second sub line area WA1b. The line structure (line arrangement structure) of the fourth sub line area WA2b can be symmetrical to the line structure (line arrangement structure) of the second sub line area WA1b.

The third line area WA3 can include data lines DL and power lines LIA_P, and may not include the data link lines LIA.

Because the data link lines LIA are not disposed in the third line area WA3, the data lines DL disposed in the third line area WA3 can be directly supplied with the data voltage VDATA through the data link lines LIN disposed in the non-active area NA, without passing through the data link lines LIA. The data line DL disposed in the third line area WA3 can have the length corresponding to the length in the column direction of the active area AA.

The power lines LIA_P disposed in the third line area WA3 can include vertical power lines VLIA_P and horizontal power lines HLIA_P.

The vertical power line VLIA_P disposed in the third line area WA3 can have the length corresponding to the length in the column direction of the active area AA.

The horizontal power line HLIA_P disposed in the third line area WA3 can be disposed to be disconnected from the horizontal data link line HLIA disposed in the same row. Accordingly, the horizontal power line HLIA_P disposed in the third line area WA3 can have the length shorter than the length in the row direction of the active area AA. The horizontal power lines HLIA_P disposed in the third line area WA3 can have different lengths.

Hereinafter, a power line structure associated with a bezel-reduced data link structure in the display panel 110 according to example embodiments of the disclosure is described in more detail.

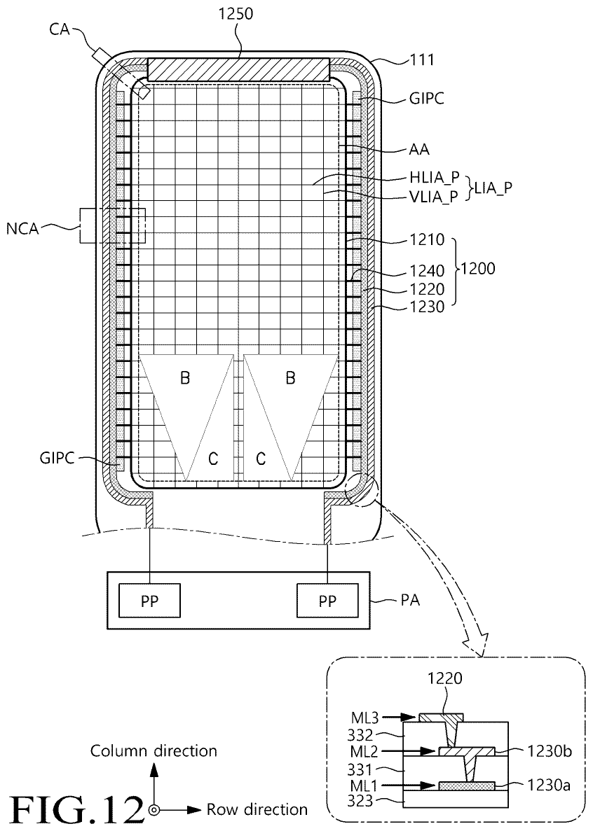

FIG. 12 illustrates a power line structure of a display panel 110 according to example embodiments of the disclosure. FIG. 12 is a view in terms of a power line structure, and a data link structure is omitted for convenience of description. FIG. 11 can also be referred to for the description of the power line structure related to the data link structure.

Referring to FIG. 12, a display panel (110) according to example embodiments of the disclosure can include a substrate (111) including an active area (AA) and a non-active area (NA), a plurality of data lines (DL), and a plurality of data link lines (LIAs). The active area AA can include a plurality of subpixels SP. The non-active area NA can be positioned outside the active area AA or around the active area AA. Each of the plurality of data lines DL can extend in the column direction within the active area AA. The plurality of data link lines LIA can be electrically connected to the plurality of data lines DL in the active area AA.

The power line structure in the display panel 110 according to example embodiments of the disclosure can include a plurality of power lines LIA_P disposed in the active area AA.

The plurality of power lines LIA_P can be electrically connected to each other.

The plurality of power lines LIA_P can be disposed in the same metal layer (e.g., the first metal layer ML1 and the second metal layer ML2) as at least one of the plurality of data link lines LIA.

The power line structure in the display panel 110 according to example embodiments of the disclosure can include a plurality of power lines LIA_P arranged in a mesh form.

The plurality of power lines LIA_P can include a plurality of horizontal power lines HLIA_P and a plurality of vertical power lines VLIA_P crossing each other. The plurality of horizontal power lines HLIA_P each can extend in the row direction in the active area AA. The plurality of vertical power lines VLIA_P each can extend in the column direction in the active area AA and can be electrically connected to the plurality of horizontal power lines VLIA_P.

The power line structure in the display panel 110 according to example embodiments of the disclosure can be disposed in the non-active area NA. A power pattern 1200 electrically connected to at least one of the plurality of power lines LIA_P can be further included. For example, the power pattern can be disposed in the non-display area NA and electrically connected to at least one of the plurality of power lines LIA_P.

For example, the power pattern 1200 can be connected to all or some of the plurality of horizontal power lines HLIA_P among the plurality of power lines LIA_P. As another example, the power pattern 1200 can be connected to all or some of the plurality of vertical power lines VLIA_P among the plurality of power lines LIA_P. As another example, the power pattern 1200 can be connected to all or some of the plurality of horizontal power lines HLIA_P, and can be connected to all or some of the plurality of vertical power lines VLIA_P.

A power voltage can be applied to the power pattern 1200.

For example, the power voltage applied to the power pattern 1200 can be the second driving common voltage VSS corresponding to the base voltage. Accordingly, the power voltage applied to the common electrode CE can be applied to the power pattern 1200. The power pattern 1200 can be electrically connected to the common electrode CE.

In order to describe the power line structure according to example embodiments of the disclosure in more detail, a bezel-reduced data link structure associated with the power line structure according to example embodiments of the disclosure is further described briefly.

The bezel-reduced data link structure of the display panel 110 according to example embodiments of the disclosure can include a plurality of data link lines LIA disposed in the active area AA. The plurality of data link lines LIA can be electrically connected to the plurality of data lines DL, and can transfer the data voltage VDATA to the plurality of data lines DL.

The plurality of data link lines LIA disposed in the active area AA can include a plurality of vertical data link lines VLIA each extending in the column direction in the active area AA, and a plurality of horizontal data link lines HLIA each extending in the row direction in the active area AA.

The metal layer where the plurality of power lines LIA_P are disposed can be connected to the metal layer where the plurality of data link lines LIA are disposed. For example, the plurality of horizontal power lines HLIA_P can be disposed in the first metal layer ML1 where the plurality of horizontal data link lines HLIA are disposed, and the plurality of vertical power lines VLIA_P can be disposed in the second metal layer ML2 where the plurality of vertical data link lines VLIA are disposed. However, without limitations thereto, various changes can be made to the metal layer where the plurality of power lines LIA_P are disposed in association with the metal layer where the plurality of data link lines LIA are disposed. Also, the plurality of horizontal power lines HLIA_P and the plurality of horizontal data link lines HLIA can be disposed to be spaced apart from each other, and the plurality of vertical power lines VLIA_P and the plurality of vertical data link lines VLIA can be disposed to be spaced apart from each other.

The active area AA can include a first area Ain which a plurality of vertical data link lines VLIA and a plurality of horizontal data link lines HLIA are not disposed, a second area B in which a plurality of horizontal data link lines HLIA are disposed, and a third area C in which a plurality of vertical data link lines VLIA are disposed. In FIG. 12, the first area A is not show to prevent confusion in the drawings, but the rest other than the second area B and the third area C can be the first area A.

A first portion of first area A can be positioned at an upper end (or an upper side) of the two second areas B, a second portion of first area A can be positioned between the two third areas C, or a third portion of first area A can be positioned outside each of the two second areas B.

The plurality of power lines LIA_P can extend from the first area A to at least a portion of the second area B or the third area C. At least some of the plurality of power lines LIA_P can have a length different from that of the rest. This is substantially the same as what has been described with reference to FIG. 11, and thus a description thereof is omitted.

The plurality of vertical data link lines VLIA and the plurality of horizontal data link lines HLIA can be electrically connected in the boundary area between the second area B and the third area C. The plurality of horizontal data link lines HLIA and the plurality of data lines DL can be electrically connected at the boundary between the second area B and the first area A.

For example, the plurality of vertical data link lines VLIA can include a first vertical data link line VLIA and a second vertical data link line VLIA disposed further outside than the first vertical data link line VLIA. The plurality of horizontal data link lines HLIA can include a first horizontal data link line HLIA electrically connected to the first vertical data link line VLIA and a second horizontal data link line HLIA electrically connected to the second vertical data link line VLIA. In this case, the first vertical data link line VLIA can have the length longer than the length of the second vertical data link line VLIA, or the first horizontal data link line HLIA can have the length longer than the length of the second horizontal data link line HLIA.

The power line structure of the display panel 110 according to example embodiments of the disclosure can further include a merged electrode 1250 electrically connected to at least one of the plurality of power lines LIA_P. For example, the merged electrode 1250 can be electrically connected to the plurality of vertical power lines VLIA_P.

The merged electrode 1250 can be disposed in the non-active area NA. For example, the merged electrode 1250 can be disposed in the non-active area NA, but can be disposed on the opposite side (the third non-active area NA3 of FIG. 4) of the pad area PA with respect to the active area AA. However, the position of the merged electrode 1250 is not limited thereto and can be variously modified.

In the power line structure of the display panel 110 according to example embodiments of the disclosure, the power pattern 1200 can include a first power pattern 1210 electrically connected to the plurality of horizontal power lines HLIA_P and disposed to surround the outer periphery of the active area AA.

In the power line structure of the display panel 110 according to example embodiments of the disclosure, the power pattern 1200 can further include a second power pattern 1220 disposed outside the first power pattern 1210, and a plurality of connection patterns 1240 electrically connecting the first power pattern 1210 and the second power pattern 1220.

For example, the second power pattern 1220 can be configured as a mesh-type electrode having at least one opening, but embodiments of the disclosure are not limited thereto. As another example, the second power pattern 1220 can be configured in the form of a plate electrode without an opening, but embodiments of the disclosure are not limited thereto.

In the power line structure of the display panel 110 according to example embodiments of the disclosure, the power pattern 1200 can further include a third power pattern 1230. The third power pattern 1230 can be disposed outside the second power pattern 1220. The third power pattern 1230 can be electrically connected to the second power pattern 1220.

For example, the third power pattern 1230 can be formed of one electrode, but embodiments of the disclosure are not limited thereto.

As another example, the third power pattern 1230 can be formed of two or more electrodes disposed on different metal layers. For example, the third power pattern 1230 can include a lower power pattern 1230a and an upper power pattern 1230b electrically connected to each other. The lower power pattern 1230a and the upper power pattern 1230b can be disposed in different metal layers to be electrically connected through a contact hole.

For example, the lower power pattern 1230a can be disposed in the first metal layer ML1, and the upper power pattern 1230b can be disposed in the second metal layer ML2, and the upper power pattern 1230b can be electrically connected to the lower power pattern 1230a disposed in the first metal layer ML1 through a hole of a first insulation layer 331 between the first metal layer ML1 and the second metal layer ML2.

The display device 100 according to example embodiments of the disclosure can include a substrate 111 including an active area AA where an image is displayed and a non-active area NA, a plurality of data lines DL, a plurality of pixel electrodes PE, and a common electrode CE. The non-active area NA can be outside or around the active area AA. A plurality of data lines DL can transfer data signals for displaying an image. The plurality of pixel electrodes PE can be disposed in the active area AA. The common electrode CE can overlap the plurality of pixel electrodes PE.

The display device 100 according to example embodiments of the disclosure can include a plurality of data link lines LIA electrically connected to the plurality of data lines DL and disposed in the active area AA, as a bezel-reduced data link structure.

The display device 100 according to example embodiments of the disclosure can include a plurality of power lines LIA_P disposed in a mesh form in the active area AA and electrically connected to the common electrode CE or to which a power voltage applied to the common electrode CE is applied, as a power line structure associated with the bezel-reduced data link structure.

According to the display device 100 according to example embodiments of the disclosure, the plurality of power lines LIA_P can be disposed in the same metal layer as the plurality of data link lines LIA.

The display device 100 according to example embodiments of the disclosure can further include a merged electrode 1250 to which the plurality of power lines LIA_P are electrically connected.

The display device 100 according to example embodiments of the disclosure can further include a power pattern 1200 electrically connected to at least one of the plurality of power lines LIA_P or electrically connected to the merged electrode 1250, and disposed in the non-active area NA.

According to the display device 100 according to example embodiments of the disclosure, the power pattern 1200 can include a first power pattern 1210 disposed in the same metal layer as at least some of the plurality of data link lines LIA and disposed outside the active area AA.

According to the display device 100 according to example embodiments of the disclosure, the power pattern 1200 can include a second power pattern 1220 disposed in the same metal layer as the plurality of pixel electrodes PE and disposed outside the active area AA.

According to the display device 100 according to example embodiments of the disclosure, the power pattern 1200 can further include a third power pattern 1230 disposed outside the second power pattern 1220 and electrically connected to the second power pattern 1220.

According to the display device 100 according to example embodiments of the disclosure, the power pattern 1200 can further include a plurality of connection patterns 1240 electrically connecting the first power pattern 1210 and the second power pattern 1220.

The plurality of horizontal power lines HLIA_P can be disposed in the first metal layer ML1.

The plurality of vertical power lines VLIA_P can be disposed in the second metal layer ML2.

The merged electrode 1250 can be disposed in the first metal layer ML1 or the second metal layer ML2, but embodiments of the disclosure are not limited thereto. Alternatively, the merged electrode 1250 can have a multilayer electrode structure disposed on both the first metal layer ML1 and the second metal layer ML2, but embodiments of the disclosure are not limited thereto.

The first power pattern 1210 can be disposed in the second metal layer ML2. The second metal layer ML2 can be a metal layer different from the first metal layer ML1.

The second power pattern 1220 can be disposed in the third metal layer ML3. The third metal layer ML3 can be a metal layer different from the first metal layer ML1 and the second metal layer ML2.

The lower power pattern 1230a and the upper power pattern 1230b included in the third power pattern 1230 can be disposed in different metal layers and can be electrically connected through a contact hole.

The lower power pattern 1230a of the third power pattern 1230 can be disposed in the first metal layer ML1 together with the plurality of horizontal power lines HLIA_P, without being limited thereto.

The upper power pattern 1230b of the third power pattern 1230 can be disposed in the second metal layer ML2 together with the plurality of vertical power lines VLIA_P, without being limited thereto.

As one example, upper power pattern 1230b of the third power pattern 1230 can be electrically connected to the lower power pattern 1230a of the third power pattern 1230 through a hole passing through a first insulation layer 331.

The upper power pattern 1230b of the third power pattern 1230 can be electrically connected to the lower power pattern 1230a of the third power pattern 1230 through a hole of the first planarization layer 331, which is a first insulation layer between the first metal layer ML1 and the second metal layer ML2.

As one example, the second power pattern 1220 can be electrically connected to the upper power pattern 1230b of the third power pattern 1230 through a hole passing through the second planarization layer 332.

The second power pattern 1220 can be electrically connected to the upper power pattern 1230b of the third power pattern 1230 through a hole of the second planarization layer 332, which is a second insulation layer between the second metal layer ML2 and the third metal layer ML3.

The display panel 110 according to example embodiments of the disclosure can further include a gate-in-panel circuit GIPC disposed in the non-active area NA. The gate-in-panel circuit GIPC can be a gate driving circuit 130 of a gate-in-panel (GIP) type, without being limited thereto.

The gate-in-panel circuit GIPC can overlap at least one of the second power pattern 1220 and the connection pattern 1240.

The gate-in-panel circuit GIPC can be disposed inside the third power pattern 1230. For example, the gate-in-panel circuit GIPC may not overlap the third power pattern 1230.

According to the power line structure according to example embodiments of the disclosure, the power voltage can be distributed and supplied through the power line structure. Accordingly, it is possible to alleviate or prevent the heat concentration that occurs when the power voltage is concentrated at a specific position. For example, since the supply path of the power voltage increases, heat generation in which the power voltage is concentrated in the corner area of the display panel can be alleviated or prevented. For example, since four surfaces of the power pattern 1220 are configured in a mesh form by connecting the plurality of power lines LIA_P to the power pattern 1220, heat generation in the corner area under the display panel can be alleviated or prevented.

Further, according to the power line structure according to example embodiments of the disclosure, it is possible to reduce an undesired drop of the power voltage. Accordingly, the power voltage can be normally supplied to the entire area (e.g., the whole common electrode CE) of the display panel 110 even without increasing the power voltage input to the display panel 110 considering a voltage drop.

Hereinafter, the power line structure according to example embodiments of the disclosure described above is briefly described for each of the main areas A, B, and C.

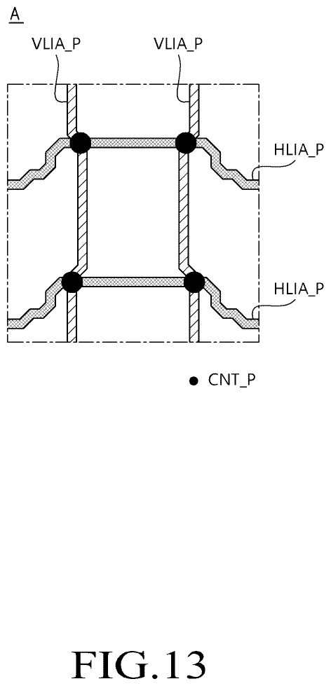

FIG. 13 illustrates a first area A of a display panel 110 according to example embodiments of the disclosure.

Referring to FIG. 13, the first area A in the active area AA of the display panel 110 according to example embodiments of the disclosure can be an area in which data link lines LIA are not disposed.

In the first area A, the horizontal power lines HLIA_P and the vertical power lines VLIA_P can be disposed by utilizing the metal layers ML1 and ML2 where the data link lines LIA are disposed.

In the first area A, the horizontal power lines HLIA_P each can be disposed to extend in the row direction. In the first area A, the vertical power lines VLIA_P each can be disposed to extend in the column direction, without being limited thereto.

In a partial area of the first area A, the horizontal power lines HLIA_P and the vertical power lines VLIA_P can cross each other. In a partial area of the first area A, the horizontal power lines HLIA_P and the vertical power lines VLIA_P can overlap each other. In a partial area of the first area A, the horizontal power lines HLIA_P and the vertical power lines VLIA_P can be electrically connected to each other.

In a partial area of the first area A, the horizontal power lines HLIA_P and the vertical power lines VLIA_P can be electrically connected to each other through the first power connection hole CNT_P1. The first power connection hole CNT_P1 can be a contact hole disposed in the active area AA.

The horizontal power lines HLIA_P and the vertical power lines VLIA_P can be disposed in different metal layers. The horizontal power lines HLIA_P can be disposed in the first metal layer ML1, and the vertical power lines VLIA_P can be disposed in the second metal layer ML2, without being limited thereto.

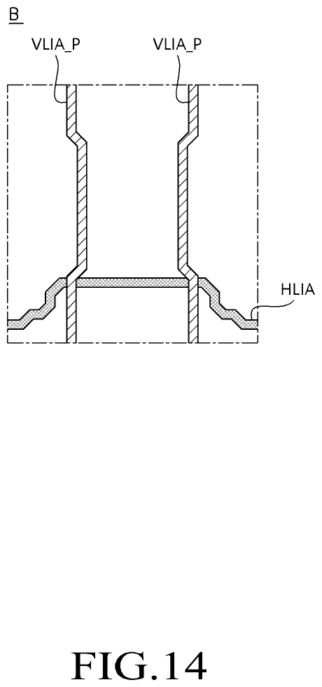

FIG. 14 illustrates a second area B of a display panel 110 according to example embodiments of the disclosure.

Referring to FIG. 14, in the second area B of the active area AA of the display panel 110 according to example embodiments of the disclosure, horizontal data link lines HLIA among the data link lines LIA can be disposed, and vertical power lines VLIA_P can be disposed.

In the second area B, the horizontal data link lines HLIA each can be disposed to extend in the row direction. In the second area B, the vertical power lines VLIA_P each can be disposed to extend in the column direction, without being limited thereto.

In a partial area of the second area B, the horizontal data link lines HLIA and the vertical power lines VLIA_P can cross each other. In the second area B, the horizontal data link lines HLIA and the vertical power lines VLIA_P can overlap each other.

In a partial area of the second area B, the horizontal data link lines HLIA and the vertical power lines VLIA_P can be disposed in different metal layers. In a partial area of the second area B, the horizontal data link lines HLIA can be disposed in the first metal layer ML1, and the vertical power lines VLIA_P can be disposed in the second metal layer ML2, without being limited thereto.

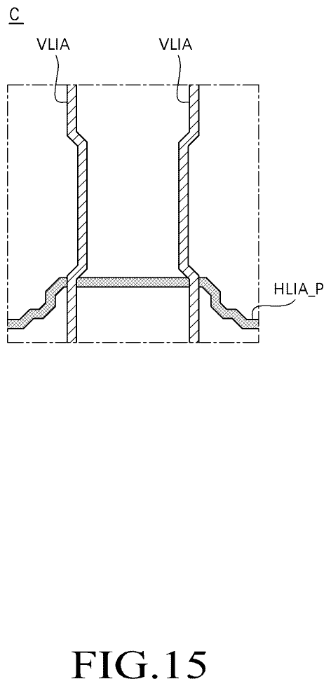

FIG. 15 illustrates a third area C of a display panel 110 according to example embodiments of the disclosure.

Referring to FIG. 15, in the third area C of the active area AA of the display panel 110 according to example embodiments of the disclosure, vertical data link lines VLIA among the data link lines LIA can be disposed, and horizontal power lines HLIA_P can be disposed.

In the third area C, the vertical data link lines VLIA each can be disposed to extend in the column direction, and the horizontal power lines HLIA_P each can be disposed to extend in the row direction, without being limited thereto.

In a partial area of the third area C, the vertical data link lines VLIA and the horizontal power lines HLIA_P can cross each other. In a partial area of the third area C, the vertical data link lines VLIA and the horizontal power lines HLIA_P can overlap each other.

In a partial area of the third area C, the vertical data link lines VLIA and the horizontal power lines HLIA_P can be disposed in different metal layers. In a partial area of the third area C, the vertical data link lines VLIA can be disposed in the second metal layer ML2, and the horizontal power lines HLIA_P can be disposed in the first metal layer ML1.

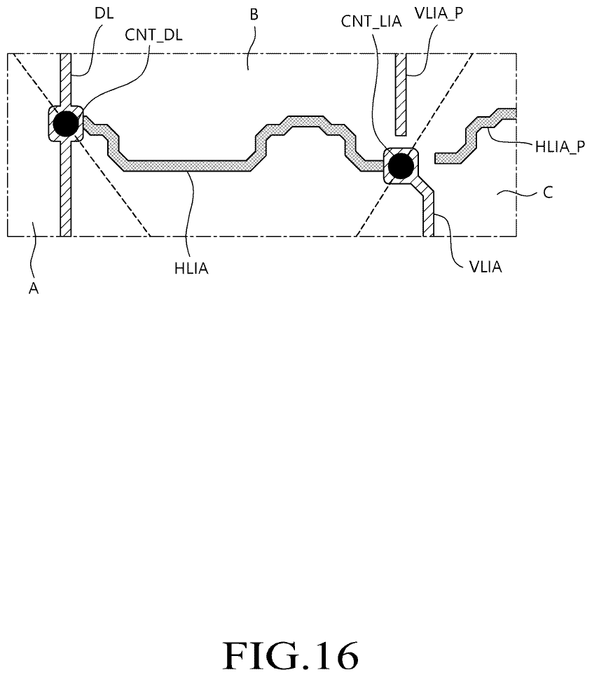

FIG. 16 illustrates a boundary area between a second area B and a third area C of a display panel 110 according to example embodiments of the disclosure.

Referring to FIG. 16, the boundary area between the second area B and the third area C can be an area in which the vertical data link line VLIA and the horizontal data link line HLIA are electrically connected.

The vertical power line VLIA_P, the vertical data link line VLIA and the data line DL each can be disposed to extend in the column direction, and the horizontal data link line HLIA and the horizontal power line HLIA_P each can be disposed to extend in the row direction, without being limited thereto.

The vertical data link line VLIA and the horizontal data link line HLIA can be electrically connected through the link line connection hole CNT_LIA. The horizontal data link line HLIA can be electrically connected to the corresponding data line DL through the data line connection hole CNT_DL.

In the boundary area between the second area B and the third area C, the horizontal power line HLIA_P disposed in the same row as the horizontal data link line HLIA can be disposed. The horizontal power line HLIA_P can be disposed to be disconnected from the horizontal data link line HLIA disposed in the same row.

In the boundary area between the second area B and the third area C, the vertical power line VLIA_P disposed in the same column as the vertical data link line VLIA can be disposed. The vertical power line VLIA_P can be disposed to be disconnected from the vertical data link line VLIA disposed in the same column.

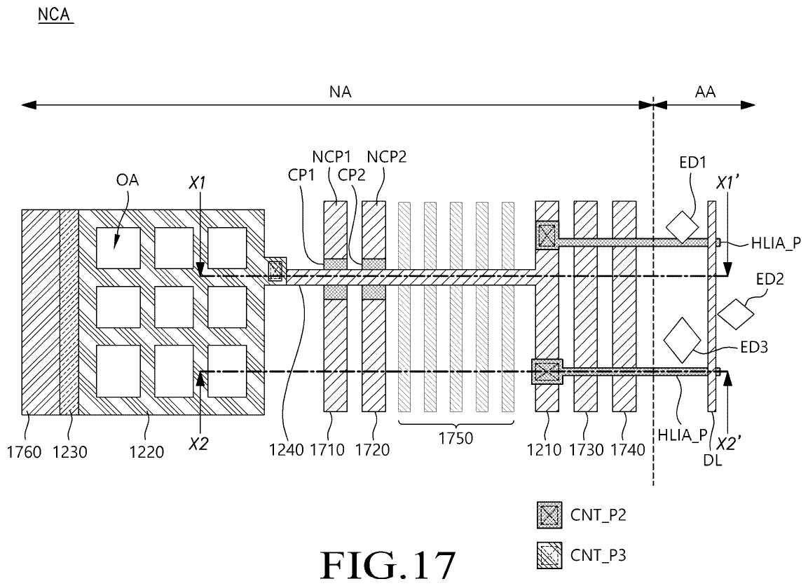

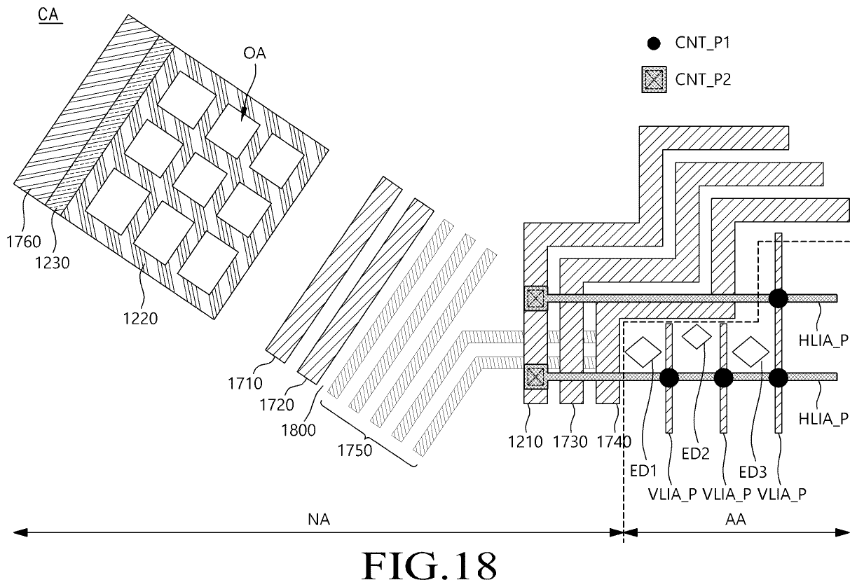

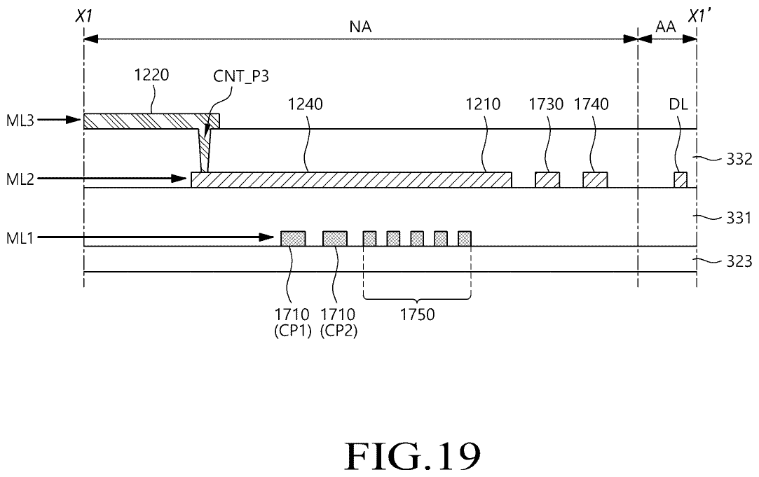

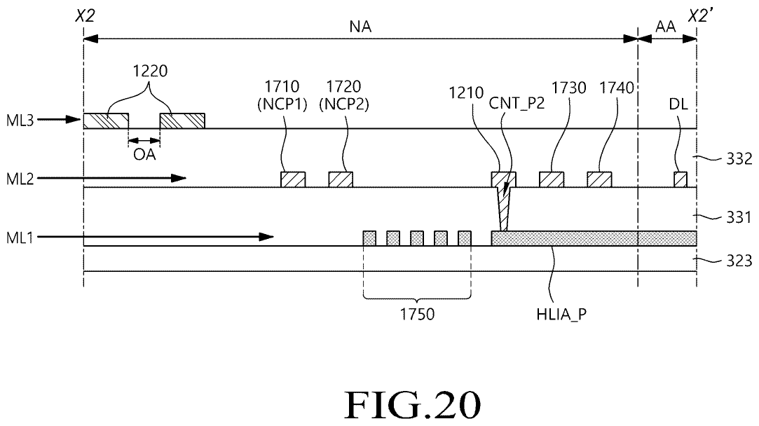

Hereinafter, the power line structure in the non-corner area NCA and the power line structure in the corner area CA of FIG. 12 are described with reference to FIGS. 17 and 18. The structure or vertical structure of the power line structure is described with reference to FIGS. 19 and 20.

FIG. 17 is a plan view illustrating a non-corner area NCA in a display panel 110 according to example embodiments of the disclosure. FIG. 18 is a plan view illustrating a corner area CA in a display panel 110 according to example embodiments of the disclosure. FIG. 19 is a cross-sectional view taken along line X1-X1′ of FIG. 17. FIG. 20 is a cross-sectional view taken along line X2-X2′ of FIG. 17.

Referring to FIGS. 17 and 18, the power line structure of the display panel 110 according to example embodiments of the disclosure can include a plurality of power lines LIA_P including horizontal power lines HLA_P and vertical power lines VLIA_P, a first power pattern 1210, a second power pattern 1220, and a third power pattern 1230.

Referring to FIG. 17, the power line structure of the display panel 110 according to example embodiments of the disclosure can further include a connection pattern 1240 connecting the first power pattern 1210 and the second power pattern 1220.

Referring to FIGS. 17 and 18, the plurality of power lines LIA_P including the horizontal power lines HLIA_P and the vertical power lines VLIA_P can be disposed in the active area AA, and the first power pattern 1210, the connection pattern 1240, the second power pattern 1220, and the third power pattern 1230 can be disposed in the non-active area NA.

The horizontal power lines HLIA_P, the vertical power lines VLIA_P, the first power pattern 1210, the second power pattern 1220, and the third power pattern 1230 all can be disposed in each of the non-corner area NCA and the corner area CA.

The plurality of connection patterns 1240 can be disposed in the non-corner area NCA but may not be disposed in the corner area CA, but embodiments of the disclosure are not limited thereto. As another example, the plurality of connection patterns 1240 can be disposed in both the non-corner area NCA and the corner area CA, but embodiments of the disclosure are not limited thereto.

The presence or absence of the plurality of connection patterns 1240 in the corner area CA can vary depending on whether there is a pattern or line to be disposed in the second metal layer ML2 in which the plurality of connection patterns 1240 are disposed between the first power pattern 1210 and the second power pattern 1220 in the corner area CA.

When there is no pattern or line to be disposed in the second metal layer ML2 between the first power pattern 1210 and the second power pattern 1220 in the corner area CA, the connection pattern 1240 can be present in the corner area CA.

If there is inevitably a pattern or line to be disposed in the second metal layer ML2 between the first power pattern 1210 and the second power pattern 1220 in the corner area CA, the connection pattern 1240 may not be present in the corner area CA.

In the corner area CA, when a pattern or line disposed in an area between the first power pattern 1210 and the second power pattern 1220 must be disposed in the second metal layer ML2, the connection pattern 1240 may not be present in the corner area CA.

In the corner area CA, when the pattern or the line may not be configured in a jumping structure in the area between the first power pattern 1210 and the second power pattern 1220, the connection pattern 1240 may not be present in the corner area CA.

In the non-corner area NCA and the corner area CA, the horizontal power lines HLIA_P can extend from the active area AA to the non-active area NA to be connected to the first power pattern 1210 disposed in the non-active area NA. In the active area AA, the horizontal power lines HLIA_P and the vertical power lines VLIA_P can be electrically connected to each other through the first power connection holes CNT_P1. In the active area AA, the light emitting elements ED1, ED2, and ED3 can be disposed around the horizontal power lines HLIA_P and the vertical power lines VLIA_P.

The horizontal power lines HLIA_P can be electrically connected to the first power pattern 1210 through the second power connection holes CNT_P2. The second power connection hole CNT_P2 can be a contact hole present in the non-active area NA.

Referring to FIG. 17, in the non-corner area NCA, the first power pattern 1210 can be electrically connected to the second power pattern 1220 through the connection pattern 1240. The second power pattern 1220 and the connection pattern 1240 can be electrically connected through the third power connection hole CNT_P3.

Each of the plurality of connection patterns 1240 can correspond to a protrusion protruding from the first power pattern 1210 in the row direction. For example, each of the plurality of connection patterns 1240 can be integrated with the first power pattern 1210.

Referring to FIGS. 17 and 18, the second power pattern 1220 can be configured as a mesh-type electrode having at least one opening. However, embodiments of the disclosure are not limited thereto.

The display panel 110 according to example embodiments of the disclosure can further include a plurality of signal lines 1710 and 1720 disposed between the first power pattern 1210 and the second power pattern 1220.

The plurality of signal lines 1710 and 1720 can include a first signal line 1710 for transferring a first signal and a second signal line 1720 for transferring a second signal.

For example, the driving signal can include two or more of an initialization voltage, a bias voltage, a reference voltage, a first pixel electrode reset voltage (a first anode reset voltage), and a second pixel electrode reset voltage (a second anode reset voltage), but embodiments of the disclosure are not limited thereto. The driving signal can be a voltage (DC voltage) having a constant voltage level or a voltage (AC voltage) having a variable voltage level.

Referring to FIG. 17, the plurality of signal lines 1710 and 1720 disposed between the first power pattern 1210 and the second power pattern 1220 can extend in the column direction and can cross at least one of the plurality of connection patterns 1240.

Each of the plurality of signal lines 1710 and 1720 can include crossing portions CP1 and CP2 crossing and overlapping at least one connection pattern 1240, and non-crossing portions NCP1 and NCP2 not crossing and not overlapping at least one connection pattern 1240. In each of the plurality of signal lines 1710 and 1720, the non-crossing portions NCP1 and NCP2 can be portions other than the crossing portions CP1 and CP2.

The crossing portions CP1 and CP2 in each of the plurality of signal lines 1710 and 1720 can be disposed in a first metal layer ML1 different from the second metal layer ML2 where the connection pattern 1240 is disposed. In each of the plurality of signal lines 1710 and 1720, the non-crossing portions NCP1 and NCP2 can be disposed in the same second metal layer ML2 as the connection pattern 1240.

In each of the plurality of signal lines 1710 and 1720, the structure in which the cross portions CP1 and CP2 overlapping (crossing) the connection pattern 1240 and the non-cross portions NCP1 and NCP2 not overlapping (crossing) the connection pattern 1240 are disposed in different metal layers can be referred to as a jumping structure.

Referring to FIGS. 17 and 18, the plurality of signal lines disposed between the first power pattern 1210 and the second power pattern 1220 can further include gate driving-related signal lines 1750 for transferring gate driving-related signals. For example, the gate driving-related signals can include gate clock signals, a high-level gate voltage, and a low-level gate voltage, but embodiments of the disclosure are not limited thereto. The gate driving-related signals can further include various control signals (e.g., a reset signal, a start signal, etc.) for gate driving.

For example, the gate driving-related signal lines 1750 can be disposed in a metal layer (e.g., the first metal layer ML1) different from the connection pattern 1240.

As another example, each of the gate driving-related signal lines 1750 can include a portion disposed in the same metal layer as the connection pattern 1240. In this case, the gate driving-related signal line 1750 can have a jumping structure. For example, the gate driving-related signal line 1750 can include a crossing portion crossing and overlapping at least one connection pattern 1240 and a non-crossing portion not crossing and not overlapping at least one connection pattern 1240. In the gate driving-related signal line 1750, the non-crossing portion can be a portion other than the crossing portion. The crossing portion of the gate driving-related signal line 1750 can be disposed in the first metal layer ML1. In the gate driving-related signal line 1750, the non-crossing portion can be electrically connected to the crossing portion and can be disposed in the same second metal layer ML2 as the connection pattern 1240.

The display panel 110 according to example embodiments of the disclosure can further include a plurality of signal lines 1730 and 1740 disposed between the display area AA and the first power pattern 1210.

The plurality of signal lines 1730 and 1740 disposed between the display area AA and the first power pattern 1210 can further include a third signal line 1730 for transferring a third signal and a fourth signal line 1740 for transferring a fourth signal.

The third signal and the fourth signal can be driving signals necessary for driving the plurality of subpixels SP. For example, the driving signal can include two or more of an initialization voltage, a bias voltage, a reference voltage, a first pixel electrode reset voltage (a first anode reset voltage), and a second pixel electrode reset voltage (a second anode reset voltage), but embodiments of the disclosure are not limited thereto. The driving signal can be a voltage (DC voltage) having a constant voltage level or a voltage (AC voltage) having a variable voltage level.

A bank open area 1760 in which an opening of the bank 333 is formed can be present outside the third power pattern 1230.

Referring to FIGS. 19 and 20, the display panel 110 according to example embodiments of the disclosure can include insulation layers including a second interlayer insulation layer 323, a first planarization layer 331, and a second planarization layer 332, and metal layers including a first metal layer ML1, a second metal layer ML2, and a third metal layer ML3 for a power line structure, but embodiments of the disclosure are not limited thereto.

The first metal layer ML1 can be disposed on the second interlayer insulation layer 323. Specifically, the first metal layer ML1 can be disposed on a portion of the second interlayer insulation layer 323. The first metal layer ML1 can be disposed between the second interlayer insulation layer 323 and the first planarization layer 331.

The second metal layer ML2 can be disposed on the first planarization layer 331. Specifically, the second metal layer ML2 can be disposed on a portion of the first planarization layer 331. The second metal layer ML2 can be disposed between the first planarization layer 331 and the second planarization layer 332.

The third metal layer ML3 can be disposed on the second planarization layer 332. Specifically, the third metal layer ML3 can be disposed on a portion of the second planarization layer 332.

The horizontal power line HLIA_P can be disposed in the first metal layer ML1. The vertical power line VLIA_P connected to the horizontal power line HLIA_P in the active area AA can be disposed in the second metal layer ML2.

The merged electrode 1250 connected to the vertical power line VLIA_P can be disposed in the first metal layer ML1 or the second metal layer ML2. Alternatively, the merged electrode 1250 can have a multilayer electrode structure disposed on both the first metal layer ML1 and the second metal layer ML2, but embodiments of the disclosure are not limited thereto.

The first power pattern 1210 can be disposed in the second metal layer ML2.

The first power pattern 1210 can be electrically connected to the horizontal power line HLIA_P extending from the active area AA to the non-active area NA through the hole passing through the first planarization layer 331. The hole of the first planarization layer 331 can correspond to the second power connection hole CNT_P2.

The first power pattern 1210 can include a connection pattern 1240. The connection pattern 1240 can protrude outward.

The second power pattern 1220 can be disposed in the third metal layer ML3.

The second power pattern 1220 can be electrically connected to the connection pattern 1240 protruding from the first power pattern 1210 through a hole of the second planarization layer 332. The hole of the second planarization layer 332 can correspond to the third power connection hole CNT_P3.

The third signal line 1730 and the fourth signal line 1740 can be disposed in the second metal layer ML2.

In the first signal line 1710 and the second signal line 1720, the crossing portions CP1 and CP2 overlapping the connection pattern 1240 can be disposed in the first metal layer ML1, and the non-crossing portions NCP1 and NCP2 not overlapping the connection pattern 1240 can be disposed in the second metal layer ML2.

The gate driving-related signal lines 1750 can overlap the connection pattern 1240.

The gate driving-related signal lines 1750 can be disposed in the first metal layer ML1 different from the connection pattern 1240.

Hereinafter, the first metal layer ML1, the second metal layer ML2, and the third metal layer ML3 utilized in the power line structure according to example embodiments of the disclosure are described. In the following description, reference is made to FIG. 3 together.

Each of the plurality of subpixels SP can include a light emitting element ED including a pixel electrode PE, an intermediate layer EL, and a common electrode CE, and a transistor (the second transistor TFT2 of FIG. 3) for driving the light emitting element ED.

The first metal layer ML1 can be a metal layer where the source electrode or the drain electrode of the transistor is disposed. The second metal layer ML2 can be a metal layer between the source electrode or drain electrode of the transistor and the pixel electrode PE. The third metal layer ML3 can be a metal layer where the pixel electrode PE is disposed.

For example, the source electrode or drain electrode of the transistor can be disposed in the first metal layer ML1. The relay electrode RE electrically connecting the source electrode or drain electrode of the transistor and the pixel electrode PE can be disposed in the second metal layer ML2. The pixel electrode PE can be disposed in the third metal layer ML3.

Various embodiments of the disclosure described above are described below.

A display device according to various embodiments of the disclosure can comprise a substrate including an active area including a plurality of subpixels and a non-active area outside the active area, a plurality of data lines connected to the plurality of subpixels, a plurality of data link lines electrically connected to the plurality of data lines in the active area, a plurality of power lines disposed in the active area and disposed in the same metal layer as at least one of the plurality of data lines, and a power pattern disposed in the non-display area and electrically connected to at least one of the plurality of power lines.

According to various embodiments of the disclosure, the plurality of data link lines can include a plurality of first data link lines (a plurality of horizontal data link lines) each extending in a first direction (row direction) in the active area and a plurality of second data link lines (a plurality of vertical data link lines) each extending in a second direction (column direction) different from the first direction in the active area.

According to various embodiments of the disclosure, the plurality of power lines can include a plurality of first power lines (a plurality of horizontal power lines) each extending in a first direction (row direction) in the active area and a plurality of second power lines (a plurality of vertical power lines) each extending in a second direction (column direction) in the active area and electrically connected to the plurality of first power lines.

According to various embodiments of the disclosure, the plurality of first power lines can be disposed parallel to the plurality of first data link lines in the active area. The plurality of second power lines can be disposed parallel to the plurality of second data link lines in the active area.

According to various embodiments of the disclosure, the plurality of first power lines and the plurality of second power lines can be arranged in a mesh form.

The display device according to various embodiments of the disclosure can further comprise a merged electrode electrically connected to at least one of the plurality of second power lines and disposed in the non-active area.

According to various embodiments of the disclosure, at least one of the plurality of first power lines can be arranged in the same row as at least one of the plurality of first data link lines, and at least one of the plurality of second power lines can be arranged in the same column as at least one of the plurality of second data link lines.

According to various embodiments of the disclosure, the plurality of first power lines can be disposed in a first metal layer where the plurality of first data link lines are disposed. The plurality of second power lines can be disposed in a second metal layer where the plurality of second data link lines are disposed.

According to various embodiments of the disclosure, the active area can include a first area where the plurality of second data link lines and the plurality of first data link lines are not disposed, a second area where the plurality of first data link lines are disposed, and a third area where the plurality of second data link lines are disposed.

According to various embodiments of the disclosure, the plurality of power lines can extend from the first area to at least a portion of the second area or the third area, and at least some of the plurality of power lines can have a different length from a rest thereof.

According to various embodiments of the disclosure, the plurality of second data link lines and the plurality of first data link lines can be electrically connected in a boundary area between the second area and the third area.

According to various embodiments of the disclosure, the power pattern can include a first power pattern electrically connected to the plurality of first power lines and disposed outside the active area.

According to various embodiments of the disclosure, the power pattern can further include a second power pattern disposed outside the first power pattern, and a plurality of connection patterns electrically connected to the first power pattern and the second power pattern.

According to various embodiments of the disclosure, the plurality of first power lines can be disposed in a first metal layer. The first power pattern can be disposed in a second metal layer different from the first metal layer. The second power pattern can be disposed in a third metal layer different from the first metal layer and the second metal layer.

According to various embodiments of the disclosure, each of the plurality of subpixels can include a light emitting element including a pixel electrode, an intermediate layer, and a common electrode, and a transistor for driving the light emitting element. The first metal layer can be a metal layer where a source electrode or a drain electrode of the transistor is disposed. The second metal layer can be a metal layer between the source electrode or the drain electrode of the transistor and the pixel electrode. The third metal layer can be a metal layer where the pixel electrode is disposed.

According to various embodiments of the disclosure, the plurality of connection patterns can be disposed to protrude from the first power pattern in the first direction (row direction).

According to various embodiments of the disclosure, the second power pattern can be configured as a mesh-type electrode having at least one opening.

According to various embodiments of the disclosure, the power pattern can further include a third power pattern disposed outside the second power pattern and electrically connected to the second power pattern.

According to various embodiments of the disclosure, the third power pattern can include a lower power pattern and an upper power pattern electrically connected to each other. The lower power pattern, together with the plurality of first power lines, can be disposed in the first metal layer. The upper power pattern, together with the plurality of second power lines, can be disposed in the second metal layer.

According to various embodiments of the disclosure, the upper power pattern can be electrically connected to the lower power pattern disposed in the first metal layer through a hole of a first insulation layer between the first metal layer and the second metal layer.

According to various embodiments of the disclosure, the second power pattern can be electrically connected to the upper power pattern through a hole of a second insulation layer between the second metal layer and the third metal layer.

The display device according to various embodiments of the disclosure can further comprise a plurality of signal lines disposed between the first power pattern and the second power pattern, extending in the second direction (column direction), and overlapping at least one of the plurality of connection patterns.

According to various embodiments of the disclosure, the each of the plurality of signal lines can comprise crossing portions crossing at least one of the plurality of connection patterns, and non-crossing portions not crossing at least one of the plurality of connection patterns,

According to various embodiments of the disclosure, crossing portions can be disposed in a metal layer different from the metal layer where the connection patterns are disposed, and the non-crossing portions can be disposed in the same metal layer as the connection patterns.

According to various embodiments of the disclosure, the plurality of connection patterns can be disposed in a non-corner area of the substrate, but may not be disposed in a corner area of the substrate.

The display device according to various embodiments of the disclosure can further comprise a plurality of pixel electrodes, an intermediate layer on the plurality of pixel electrodes, and a common electrode on the intermediate layer. A power voltage applied to the common electrode can be applied to the power pattern.

A display device according to various embodiments of the disclosure can comprise a substrate including an active area displaying an image and a non-active area outside the active area, a plurality of data link lines electrically connected to a plurality of data lines and disposed in the active area, a plurality of pixel electrodes disposed in the active area, a common electrode overlapping the plurality of pixel electrodes, and a plurality of power lines disposed in the active area in a mesh form and electrically connected to the common electrode or receiving a power voltage applied to the common electrode.

According to various embodiments of the disclosure, the plurality of power lines can be disposed in the same metal layer as the plurality of data link lines.

The display device according to various embodiments of the disclosure can further comprise a merged electrode electrically connected to the plurality of power lines and a power pattern electrically connected to at least one of the plurality of power lines or electrically connected to the merged electrode, and disposed in the non-display area.

According to various embodiments of the disclosure, the power pattern can include a first power pattern disposed in the same metal layer as at least some of the plurality of data link lines and disposed outside the active area.

According to various embodiments of the disclosure, the power pattern can include a second power pattern disposed in the same metal layer as the plurality of pixel electrodes and disposed outside the active area.

A display device according to various embodiments of the disclosure can comprise a substrate including an active area including a plurality of subpixels and a non-active area outside the active area; a plurality of data lines connected to the plurality of subpixels; a plurality of data link lines electrically connect a plurality of pads in the non-active area and the plurality of data lines in the active area.

According to various embodiments of the disclosure, the plurality of data link lines can include a plurality of first data link lines each extending in a first direction in the active area and a plurality of second data link lines each extending in a second direction different from the first direction in the active area.

According to various embodiments of the disclosure, the plurality of second data link lines can electrically connect the plurality of pads and the plurality of first data link lines, the plurality of first data link lines can electrically connect the plurality of second data link lines and the plurality of data lines.

A vehicle according to various embodiments of the disclosure can comprise the at least one display device.

A display panel according to various embodiments of the disclosure can comprise a plurality of data lines disposed in the active area; a plurality of pads disposed in the non-active area; and a plurality of data link lines disposed in the active area and non-active area, and configured to electrically connect the plurality of pads and the plurality of data lines, wherein the plurality of data link lines include a plurality of first data link lines each extending in a first direction in the active area and a plurality of second data link lines each extending in a second direction different from the first direction in the active area, and wherein the plurality of second data link lines electrically connect the plurality of pads and the plurality of first data link lines, the plurality of first data link lines electrically connect the plurality of second data link lines and the plurality of data lines.

According to example embodiments of the disclosure, there can be provided a display device having a data link structure capable of reducing the bezel.

According to example embodiments of the disclosure, there can be provided a display device having a power line structure that enables stable transfer of power voltage.

According to example embodiments of the disclosure, there can be provided a display device having a power line structure suitable for a data link structure capable of reducing the bezel.

According to example embodiments of the disclosure, there can be provided a display device having a power line structure capable of distributively supplying a power voltage.

According to example embodiments of the disclosure, there can be provided a display device capable of alleviating or preventing heat concentration due to a power voltage.

According to example embodiments of the disclosure, there can be provided a display device having a power line structure capable of reducing an undesired voltage drop of a power voltage.

According to example embodiments of the disclosure, it is possible to reduce the weight of a display device by reducing the bezel by a data link structure capable of reducing the bezel.

According to example embodiments of the disclosure, it is possible to eliminate the need for increasing the power voltage to be input to the display panel considering a voltage drop by reducing the voltage drop of the power voltage, thereby making it possible to secure an additional voltage usage margin and achieve a low-power design.

A display device according to various example embodiments of the disclosure can be applied to mobile devices, video phones, smart watches, watch phones, wearable devices, foldable devices, rollable devices, bendable devices, flexible devices, curved devices, slidable devices, transformable devices, electronic notebooks, electronic books, portable multimedia players (PMPs), personal digital assistants (PDAs), MP3 players, mobile medical devices, desktop PCs, laptop PCs, netbook computers, workstations, navigation devices, vehicle navigations, vehicle displays, vehicle devices, theater devices, theater displays, televisions, wallpaper devices, signage devices, game consoles, laptop computers, monitors, cameras, camcorders, and home appliances.

The above-described embodiments of the disclosure are merely examples, and it will be appreciated by one of ordinary skill in the art various changes can be made thereto without departing from the scope of the disclosure. Accordingly, the embodiments set forth herein are provided for illustrative purposes, but not to limit the scope of the disclosure, and should be appreciated that the scope of the disclosure is not limited by the embodiments.

What is claimed is:

1. A display device, comprising:
a substrate including an active area and a non-active area outside the active area, the active area including a plurality of subpixels;
a plurality of data lines connected to the plurality of subpixels;
a plurality of data link lines electrically connected to the plurality of data lines in the active area;
a plurality of power lines disposed in the active area and disposed in a same metal layer as at least one of the plurality of data lines; and
a power pattern disposed in the non-display area and electrically connected to at least one of the plurality of power lines.

2. The display device of claim 1, wherein the plurality of data link lines include a plurality of first data link lines each extending in a first direction in the active area and a plurality of second data link lines each extending in a second direction in the active area, the second direction being different from the first direction, and
wherein the plurality of power lines include a plurality of first power lines disposed parallel to the plurality of first data link lines in the active area and a plurality of second power lines disposed parallel to the plurality of second data link lines in the active area.

3. The display device of claim 2, wherein the plurality of first power lines and the plurality of second power lines are arranged in a mesh form.

4. The display device of claim 2, further comprising a merged electrode electrically connected to at least one of the plurality of second power lines and disposed in the non-active area.

5. The display device of claim 2, wherein at least one of the plurality of first power lines is arranged in a same row as at least one of the plurality of first data link lines, and
wherein at least one of the plurality of second power lines is arranged in a same column as at least one of the plurality of second data link lines.

6. The display device of claim 2, wherein the active area includes:
a first area where the plurality of second data link lines and the plurality of first data link lines are not disposed;
a second area where the plurality of first data link lines are disposed; and
a third area where the plurality of second data link lines are disposed,
wherein the plurality of power lines extend from the first area to at least a portion of the second area or the third area, and
wherein at least some of the plurality of power lines has a different length from a rest of the plurality of power lines.

7. The display device of claim 6, wherein the plurality of second data link lines and the plurality of first data link lines are electrically connected in a boundary area between the second area and the third area.

8. The display device of claim 2, wherein the power pattern includes a first power pattern electrically connected to the plurality of first power lines and disposed outside the active area.

9. The display device of claim 8, wherein the power pattern further includes:
a second power pattern disposed outside the first power pattern; and
a plurality of connection patterns electrically connected to the first power pattern and the second power pattern.

10. The display device of claim 9, wherein the plurality of first power lines are disposed in a first metal layer where the plurality of first data link lines are disposed,
wherein the plurality of second power lines are disposed in a second metal layer where the plurality of second data link lines are disposed, the second metal layer being different from the first metal layer,
wherein the first power pattern is disposed in the second metal layer, and
wherein the second power pattern is disposed in a third metal layer being different from the first metal layer and the second metal layer.

11. The display device of claim 10, wherein each of the plurality of subpixels includes a light emitting element and a transistor configured to drive the light emitting element, the light emitting element including a pixel electrode, an intermediate layer, and a common electrode,
wherein the first metal layer is a metal layer where a source electrode or a drain electrode of the transistor is disposed,
wherein the second metal layer is a metal layer disposed between the pixel electrode and one of the source electrode and the drain electrode of the transistor, and
wherein the third metal layer is a metal layer where the pixel electrode is disposed.

12. The display device of claim 9, wherein the plurality of connection patterns are disposed to protrude from the first power pattern in the first direction.

13. The display device of claim 9, wherein the second power pattern is configured as a mesh-type electrode having at least one opening.

14. The display device of claim 9, wherein the power pattern further includes a third power pattern disposed outside the second power pattern and electrically connected to the second power pattern.

15. The display device of claim 14, wherein the third power pattern includes a lower power pattern and an upper power pattern electrically connected to each other,
wherein the lower power pattern, together with the plurality of first power patterns, is disposed in the first metal layer, and the upper power pattern, together with the plurality of second power lines, is disposed in the second metal layer, and
wherein the upper power pattern is electrically connected to the lower power pattern disposed in the first metal layer through a hole of a first insulation layer disposed between the first metal layer and the second metal layer.

16. The display device of claim 15, wherein the second power pattern is electrically connected to the upper power pattern through a hole of a second insulation layer disposed between the second metal layer and the third metal layer.

17. The display device of claim 9, further comprising a plurality of signal lines disposed between the first power pattern and the second power pattern,
wherein the plurality of signal lines extend in the second direction, and overlap at least one of the plurality of connection patterns.

18. The display device of claim 17, wherein each of the plurality of signal lines comprises crossing portions crossing at least one of the plurality of connection patterns, and non-crossing portions not crossing at least one of the plurality of connection patterns,
wherein the crossing portions are disposed in a metal layer different from the metal layer where the plurality of connection patterns are disposed, and
wherein the non-crossing portions are disposed in the same metal layer as the plurality of connection patterns.

19. The display device of claim 9, wherein the plurality of connection patterns are disposed in a non-corner area of the substrate, but are not disposed in a corner area of the substrate.

20. The display device of claim 1, further comprising:
a plurality of pixel electrodes;
an intermediate layer on the plurality of pixel electrodes; and
a common electrode on the intermediate layer,
wherein a power voltage applied to the common electrode is applied to the power pattern.

21. A display device, comprising:
a substrate including an active area configured to display an image and a non-active area disposed outside the active area;
a plurality of data link lines electrically connected to a plurality of data lines and disposed in the active area;
a plurality of pixel electrodes disposed in the active area;
a common electrode overlapping the plurality of pixel electrodes; and
a plurality of power lines disposed in the active area in a mesh form, and either electrically connected to the common electrode or receiving a power voltage applied to the common electrode.

22. The display device of claim 21, further comprising:
a merged electrode electrically connected to the plurality of power lines; and
a power pattern electrically connected to at least one of the plurality of power lines or electrically connected to the merged electrode,
wherein the power pattern is disposed in the non-display area.

23. The display device of claim 22, wherein the power pattern includes a first power pattern disposed in a same metal layer as at least some of the plurality of data link lines, and the first power pattern is disposed outside the active area.

24. The display device of claim 22, wherein the power pattern includes a second power pattern disposed in a same metal layer as the plurality of pixel electrodes, and the second power pattern is disposed outside the active area.

25. A display device, comprising:
a substrate including an active area and a non-active area outside the active area, the active area including a plurality of subpixels;
a plurality of data lines connected to the plurality of subpixels; and
a plurality of data link lines electrically connect a plurality of pads in the non-active area and the plurality of data lines in the active area,
wherein the plurality of data link lines include a plurality of first data link lines each extending in a first direction in the active area and a plurality of second data link lines each extending in a second direction in the active area, the second direction being different from the first direction,
wherein the plurality of second data link lines electrically connect the plurality of pads and the plurality of first data link lines, and
wherein the plurality of first data link lines electrically connect the plurality of second data link lines and the plurality of data lines.

26. A vehicle, comprising:
at least one display device according to claim 1.

27. A display panel provided with an active area and a non-active area, the display panel comprising:
a plurality of data lines disposed in the active area;
a plurality of pads disposed in the non-active area; and
a plurality of data link lines disposed in the active area and the non-active area, and configured to electrically connect the plurality of pads and the plurality of data lines,
wherein the plurality of data link lines include a plurality of first data link lines each extending in a first direction in the active area and a plurality of second data link lines each extending in a second direction in the active area, the second direction being different from the first direction,
wherein the plurality of second data link lines electrically connect the plurality of pads and the plurality of first data link lines, and
wherein the plurality of first data link lines electrically connect the plurality of second data link lines and the plurality of data lines.
